(19) United States
(12) Patent Application Publication
(10) Pub. No.: US 2026/0116176 A1
(43) Pub. Date: Apr. 30, 2026

(54) THERMAL MANAGEMENT APPARATUS AND THERMAL MANAGEMENT SYSTEM FOR A VEHICLE INCLUDING THE SAME

(71) Applicants: Hyundai Motor Company, Seoul (KR); Kia Corporation, Seoul (KR)

(72) Inventors: Jong Won Kim, Hwaseong-si (KR); Dae Kyu Han, Hwaseong-si (KR)

(21) Appl. No.: 19/050,770

(22) Filed: Feb. 11, 2025

(30) Foreign Application Priority Data
Oct. 29, 2024 (KR) 10-2024-0149338

(51) Int. Cl. B60K 11/02; H05K 7/20; B60K 1/00

(52) U.S. Cl. CPC B60K 11/02; H05K 7/20318; H05K 7/20327; H05K 7/20936; B60K 2001/005

(57) ABSTRACT

A vehicle thermal management device, and a vehicle thermal management system including the same, can include a radiator configured to perform heat exchange between coolant and air, a condenser configured to perform heat exchange between refrigerant and the air, a receiver dryer configured to remove moisture from the refrigerant discharged from the condenser, the receiver dryer being configured to separate liquid refrigerant from gaseous refrigerant, and a heat exchange module connected to the radiator so as to allow the coolant to move therebetween, the heat exchange module being configured to selectively perform heat exchange between the refrigerant in the receiver dryer and the coolant supplied from the radiator.

### CROSS-REFERENCE TO RELATED APPLICATIONS

This application claims the priority and benefit of Korean Patent Application No. 10-2024-0149338, filed on October 29, 2024, which application is hereby incorporated herein by reference in its entirety.

### TECHNICAL FIELD

The present disclosure relates to a vehicle thermal management device for a vehicle.

### BACKGROUND

In general, a vehicle has a thermal management system mounted therein and configured to perform overall thermal management of the vehicle. The vehicle thermal management system manages energy required for cooling or heating of the vehicle interior and cooling or heating of a battery and a component of a power electronics (PE) system.

The vehicle thermal management system may be broadly defined as a system including a cooling system and a heating system each configured to perform indoor air conditioning and a component thermal management system using refrigerant and coolant so as to perform thermal management such as cooling or heating of a battery and parts of a PE system.

Normally, the vehicle thermal management system includes a refrigerant system in which a compressor, a condenser, a receiver dryer, an expansion valve, an evaporator, and an accumulator are connected to each other through a refrigerant line.

The above-described components of the refrigerant system are main components of an air-conditioning system for vehicle interior cooling, and refrigerant sequentially passes through the components while circulating along the refrigerant line.

The vehicle thermal management system includes a coolant system in which a water pump configured to circulate refrigerant and coolant, a chiller configured to perform heat exchange between refrigerant and coolant, and a radiator configured to perform heat exchange between coolant and air are connected to each other through a coolant line.

Further, the vehicle thermal management system may be operated in a plurality of modes including a heating mode in which heated air is supplied to the vehicle interior for heating of the vehicle interior, a cooling mode in which cooled air is supplied to the vehicle interior for cooling of the vehicle interior (air-conditioning mode), and a dehumidification mode in which air that has exchanged heat with refrigerant is supplied to the vehicle interior for dehumidification of the vehicle interior.

Among the above-described modes, refrigerant and an electric heater (for example, a positive temperature coefficient (PTC) heater) may be used when the heating mode is implemented. Further, when the refrigerant temperature is sufficiently high, heating of the vehicle interior may be performed using high-temperature refrigerant without using the electric heater.

It can be required to provide a technique capable of not only solving a problem related to high temperature and high pressure in a refrigerant system by additionally discharging heat of refrigerant to the outside in the refrigerant system through which the refrigerant circulates, but also improving interior cooling performance, battery cooling performance, and the like by stabilizing the refrigerant system. In addition, it can be also required to provide a technique capable of improving efficiency of a vehicle thermal management system including the refrigerant system.

For example, when rapid charging of a battery and cooling of the vehicle interior are simultaneously performed in an electric vehicle in summer, it is required to provide a heat exchange means capable of effectively discharging heat from the battery through coolant and an additional heat exchange means capable of effectively dissipating heat from refrigerant to secure cooling performance.

To address the problem of excessive heat load generation, a thermal management system disclosed in Korean Patent Laid-Open Publication No. 10-2022-0121931 filed on September 2, 2022 (U.S. counterpart 11,884,127) and Korean Patent Laid-Open Publication No. 10-2022-0129189 (filed on September 23, 2022) uses a water-cooled heat exchanger (water-cooled condenser) configured to perform heat exchange between refrigerant and coolant for the purpose of securing subcooling and controlling pressure. When the water-cooled heat exchanger is used, it can be necessary to additionally install related components, leading to increased system complexity.

The above information disclosed in this Background section is only for enhancement of understanding of the background of the present disclosure, and therefore it may contain information that does not form the prior art that is already publicly known, available, or in use.

### SUMMARY

The present disclosure relates to a vehicle thermal management device configured to perform heat exchange between refrigerant in a receiver dryer and coolant discharged from a radiator, and a vehicle thermal management system including the same.

An embodiment of the present disclosure can solve the above-described problems associated with the prior art. An embodiment of the present disclosure can provide a vehicle thermal management device and a vehicle thermal management system including the same, configured not only to solve a problem related to high temperature and high pressure in a refrigerant system by additionally discharging heat from refrigerant to the outside in the refrigerant system through which the refrigerant circulates, but also to improve interior cooling performance, battery cooling performance, and the like by stabilizing the system.

The advantages of an embodiment of the present disclosure are not necessarily limited to the above-mentioned advantages, and other technical advantages not mentioned herein can be understood by those skilled in the art to which the present disclosure pertains (referred to hereinafter as "those skilled in the art") from the detailed description of the example embodiments.

An embodiment of the present disclosure can provide a vehicle thermal management device including a radiator configured to perform heat exchange between coolant and air, a condenser configured to perform heat exchange between refrigerant and the air, a receiver dryer configured to remove moisture from the refrigerant discharged from the condenser, the receiver dryer being configured to separate liquid refrigerant from gaseous refrigerant, and a heat exchange module connected to the radiator so as to allow the coolant to move therebetween, the heat exchange module being configured to selectively perform heat exchange between the refrigerant in the receiver dryer and the coolant supplied from the radiator.

In an embodiment, the heat exchange module may be installed outside the receiver dryer.

In an embodiment, the heat exchange module may have a coolant flow path formed to contact an outer surface of the receiver dryer.

In an embodiment, the heat exchange module may have a coolant flow path disposed in a spiral shape around the receiver dryer.

In an embodiment, the heat exchange module may include a heat exchange part including a coolant flow path, the heat exchange part being configured to perform heat exchange between the refrigerant in the receiver dryer and the coolant passing through the coolant flow path, a bypass flow path part configured such that the coolant passes through the bypass flow path part while bypassing the heat exchange part, and a valve device configured to control a flow of the coolant so as to allow the coolant discharged from the radiator to selectively flow through the heat exchange part or the bypass flow path part.

In an embodiment, the heat exchange module may further include a main body block having a coolant inlet and a coolant outlet, wherein the coolant flow path of the heat exchange part and the bypass flow path part directly connecting the coolant inlet to the coolant outlet are formed in the main body block.

In an embodiment, the valve device may include a valve body configured to control, depending on a rotated position thereof, the flow of the coolant with respect to the bypass flow path part and the heat exchange part, an actuator configured to rotate the valve body, and a valve controller configured to control an operation of the actuator.

In an embodiment, the valve body may include a first flow path part formed to allow, at a first rotation position of the valve body, a coolant inlet of the heat exchange module and the coolant flow path of the heat exchange part to communicate with each other, a second flow path part formed to allow, at a second rotation position of the valve body, the coolant inlet and the bypass flow path part to communicate with each other, and a blocking wall formed to cause, at a third rotation position of the valve body, the coolant inlet to be simultaneously blocked from the coolant flow path and the bypass flow path part.

In an embodiment, the heat exchange module may include a main body block having a coolant inlet and a coolant outlet, wherein the main body block may include an accommodation part configured to allow at least part of the receiver dryer to be inserted thereinto, and a flow path groove formed in an inner surface of the accommodation part so as to form a coolant flow path between the coolant inlet and the coolant outlet, wherein the at least part of the receiver dryer may be inserted into the accommodation part such that the flow path groove is sealed by an outer surface of the receiver dryer.

In an embodiment, the flow path groove may be formed in the inner surface of the accommodation part so as to spirally surround a periphery of the receiver dryer inserted into the accommodation part.

In an embodiment, the receiver dryer may have a portion inserted into the accommodation part, wherein the portion may be a lower portion of the receiver dryer and is filled with the liquid refrigerant.

In an embodiment, the heat exchange module may have a coolant outlet configured to allow the coolant that has completed the heat exchange with the refrigerant to be discharged therethrough, the coolant outlet being connected to a coolant line for thermal management of a battery and a power electronics (PE) system.

An embodiment of the present disclosure can provide a vehicle thermal management system including a cooling/heating system configured to perform, using refrigerant, cooling and heating of a vehicle interior, a component thermal management system configured to perform, using the refrigerant and coolant, thermal management for a battery and a power electronics (PE) system, and a heat exchange module connected to a radiator of the component thermal management system so as to allow the coolant to move therebetween, the heat exchange module being configured to selectively perform heat exchange between the refrigerant in a receiver dryer and the coolant supplied from the radiator, the receiver dryer being installed in a condenser of the cooling/heating system.

In an embodiment, the component thermal management system may include a PE thermal management system including a first water pump, a water heater for heating of PE coolant, a PE coolant passage part provided in a component of the PE system, the radiator configured to perform heat exchange between the PE coolant and air, and a PE coolant line configured to connect the first water pump, the water heater, the PE coolant passage part, and the radiator to each other so as to allow the PE coolant to circulate therethrough, a chiller connected to a chiller refrigerant line connected to a refrigerant line of the cooling/heating system and the PE coolant line, wherein the chiller is configured to perform, while the refrigerant of the chiller refrigerant line and the PE coolant pass through the chiller, heat exchange between the refrigerant and the PE coolant, and a chiller expansion valve installed on the chiller refrigerant line on an inlet side of the chiller.

In an embodiment, the component thermal management system may further include a battery thermal management system including a second water pump, a battery coolant passage part provided in the battery, and a battery coolant line configured to connect the second water pump to the battery coolant passage part so as to allow battery coolant to circulate therethrough.

In an embodiment, the battery coolant line may be connected to the chiller, and the chiller may be configured to perform, while the refrigerant of the chiller refrigerant line, the PE coolant, and the battery coolant pass through the chiller, heat exchange between the refrigerant, the PE coolant, and the battery coolant.

In an embodiment, the PE thermal management system may further include a heater coolant line branching from the PE coolant line between the first water pump and the chiller, the heater coolant line having the water heater connected thereto and installed thereon, and a first valve installed on a branch point of the PE coolant line between the first water pump and the chiller, wherein the heater coolant line may branch from the branch point.

In an embodiment, the PE thermal management system may further include a connection line branching from the PE coolant line between the PE coolant passage part and the first water pump, the connection line being connected to the heater coolant line, and a second valve installed on a branch point of the PE coolant line between the PE coolant passage part and the first water pump, wherein the connection line branches from the branch point.

In an embodiment, the heat exchange module may be installed outside the receiver dryer.

In an embodiment, the heat exchange module may include a heat exchange part including a coolant flow path, the heat exchange part being configured to perform heat exchange between the refrigerant in the receiver dryer and the coolant passing through the coolant flow path, a bypass flow path part configured such that the coolant passes through the bypass flow path part while bypassing the heat exchange part, and a valve device configured to control a flow of the coolant so as to allow the coolant discharged from the radiator to selectively flow through the heat exchange part or the bypass flow path part.

It can be understood that the terms "vehicle", "vehicular", and other similar terms as used herein can be inclusive of motor vehicles in general, such as passenger automobiles including sport utility vehicles (SUVs), buses, trucks, various commercial vehicles, watercraft including a variety of boats and ships, aircraft, and the like, and include hybrid vehicles, electric vehicles, plug-in hybrid electric vehicles, hydrogen-powered vehicles, and other alternative fuel vehicles (e.g., fuels derived from resources other than petroleum). As referred to herein, a hybrid vehicle is a vehicle that has two or more sources of power, for example, vehicles powered by both gasoline and electricity.

### BRIEF DESCRIPTION OF THE DRAWINGS

The above and other features of the present disclosure will now be described in detail with reference to certain example embodiments thereof illustrated in the accompanying drawings, which are given hereinbelow by way of illustration, and thus are not necessarily limitative of the present disclosure, and in which:

FIG. 1 is a diagram showing a circuit configuration of a vehicle thermal management system including a vehicle thermal management device according to an embodiment of the present disclosure;

FIG. 2 is a block diagram showing a control element and an operating element in a vehicle thermal management system according to an embodiment of the present disclosure;

FIG. 3 is a diagram showing a configuration of a vehicle thermal management device according to an embodiment of the present disclosure;

FIG. 4 is a diagram showing a receiver dryer and a heat exchange module in a state of being separated from a vehicle thermal management device according to an embodiment of the present disclosure;

FIG. 5 is a plan view of the heat exchange module in an embodiment of the present disclosure;

FIG. 6 is a side view of the heat exchange module in an embodiment of the present disclosure;

FIG. 7 is a cross-sectional view taken along line "A-A" in FIG. 5;

FIG. 8 is a cross-sectional view taken along line "B-B" in FIG. 5;

FIG. 9 is a cross-sectional view taken along line "C-C" in FIG. 6;

FIG. 10 is a cross-sectional view taken along line "D-D" in FIG. 6;

FIGS. 11 to 13 are diagrams each showing the control of a valve device and a coolant flow state according to an operation mode of a heat exchange module in an embodiment of the present disclosure;

FIGS. 14 to 16 are perspective views each showing a valve body rotation position and an opening state of a valve device according to an operation mode of a heat exchange module in an embodiment of the present disclosure;

FIGS. 17 and 18 are diagrams each showing a flow of coolant and refrigerant in a vehicle thermal management device according to an embodiment of the present disclosure; and

FIGS. 19 to 27 are diagrams each showing a main operation mode of a vehicle thermal management system according to embodiments of the present disclosure.

It can be understood that the appended drawings are not necessarily to scale, presenting a somewhat simplified representation of various features illustrative of some principles of example embodiments of the present disclosure. The specific design features of example embodiments of the present disclosure as disclosed herein, including, for example, specific dimensions, orientations, locations, and shapes can be determined in part by the particular intended application and use environment.

In the figures, reference numbers can refer to the same or equivalent parts of example embodiments of the present disclosure throughout the several figures of the drawing.

### DETAILED DESCRIPTION OF ILLUSTRATIVE EMBODIMENTS

Hereinafter, reference will be made in detail to various example embodiments of the present disclosure, which are illustrated in the accompanying drawings and described below. Specific structural or functional descriptions given in connection with the example embodiments of the present disclosure are merely illustrative for the purpose of describing example embodiments according to some concepts of the present disclosure, and embodiments of the present disclosure may be implemented in various forms. It can be understood that the present description is not intended to necessarily limit the present disclosure to the example embodiments. On the contrary, the present disclosure is intended to cover not only the example embodiments, but also various alternatives, modifications, equivalents, and other embodiments, which may be included within the spirit and scopes of the present disclosure as defined by the appended claims.

In the present disclosure, terms such as "first" and/or "second" may be used to describe various components, but the components are not necessarily limited by such terms. Such terms can be used merely for the purpose of distinguishing one component from other components. For example, a first component may be referred to as a second component, and similarly, a second component may also be referred to as a first component without departing from the scopes of rights of the present disclosure.

When one component is referred to as being "connected" or "joined" to another component, the one component may be directly connected or joined to the other component, but it can be understood that other components may be present therebetween. On the other hand, when the one component is referred to as being "directly connected to" or "directly in contact with" the other component, it can be understood that other components are not present therebetween. Other expressions for the description of relationships between components, that is, "between" and "directly between" or "adjacent to" and "directly adjacent to", can be interpreted in the same manner.

Same reference numerals can represent same components throughout the specification. The terms in the specification are used to describe example embodiments and are not intended to necessarily limit the present disclosure. In this specification, an expression in a singular form also can include a plural form, unless clearly specified otherwise in context. As used herein, expressions such as "comprise" and/or "comprising" do not exclude the presence or addition of one or more components, steps, operations, and/or elements other than those described.

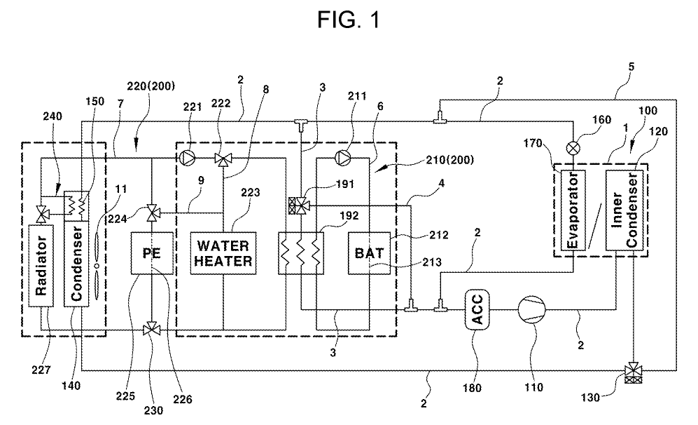

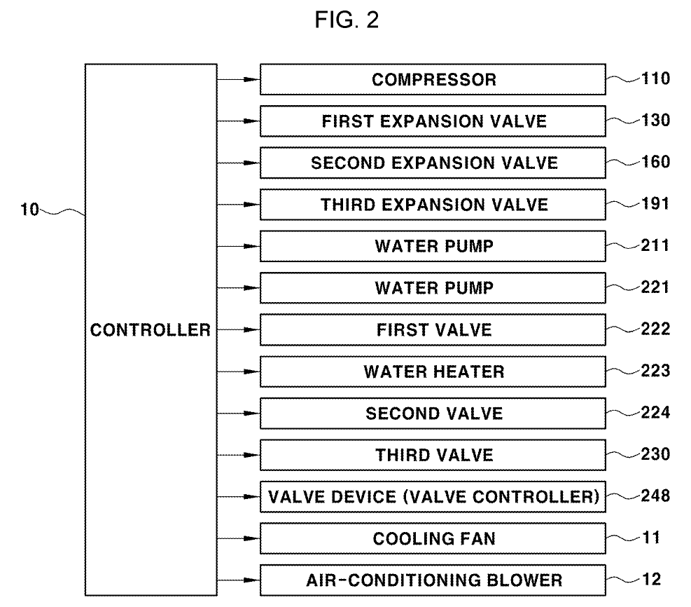

FIG. 1 is a diagram showing a circuit configuration of a vehicle thermal management system including a vehicle thermal management device according to an embodiment of the present disclosure. FIG. 2 is a block diagram showing a control element and an operating element in a vehicle thermal management system according to an embodiment of the present disclosure.

An embodiment of the present disclosure may be applied to a pure electric vehicle (EV) capable of traveling by driving a motor with battery power. An embodiment of the present disclosure may be applied to a pure electric vehicle, a hybrid electric vehicle (HEV) capable of traveling by using power from an engine and a motor, and an extended range electric vehicle (EREV) configured to use an engine only to charge a battery and to travel only using power from a motor.

In a vehicle thermal management system of an embodiment of the present disclosure, a conventional water-cooled heat exchanger (water-cooled condenser) can be removed. Instead of the water-cooled condenser, the vehicle thermal management system can have a separate heat exchange module 240 mounted therein and configured to perform heat exchange between refrigerant inside a receiver dryer 150 and coolant discharged from a radiator 227. The heat exchange module 240 can be disposed outside the receiver dryer 150, thereby making it possible not only to discharge heat from the existing water-cooled refrigerant, but also to additionally secure a subcooled area.

The vehicle thermal management system of an embodiment of the present disclosure can include a heat pump boosting thermal management circuit using a water heater 223. Conventionally, the water heater was installed on a coolant line through which battery coolant circulates. The conventional water heater is installed in a battery thermal management circuit for cooling and heating of a battery and is used only for heating of the battery.

However, in an embodiment of the present disclosure, the water heater 223 may be used not only for heating of a battery 212, but also for boosting of a heat pump and heating of a power electronics (PE) system 225, thereby utilizing the water heater 223 for various purposes.

As described above, because the water heater 223 can be also used for boosting of the heat pump, the conventional electric heater (for example, PTC heater) installed in an air-conditioning case 1 may be removed for an embodiment of the present disclosure. In an embodiment of the present disclosure, various modes may be implemented by using the heat pump boosting thermal management circuit using the water heater 223.

More specifically, as shown in the drawings, a vehicle thermal management system according to an embodiment of the present disclosure can include a cooling/heating system 100 configured to perform, using refrigerant, cooling and heating of the vehicle interior and a component thermal management system 200 configured to perform, using refrigerant and coolant, thermal management such as cooling and heating of components of the battery 212 or the PE system 225.

The cooling/heating system 100 can include a compressor 110, an internal condenser 120, a first expansion valve 130, an external condenser 140, a receiver dryer 150, a second expansion valve 160, an evaporator 170, and an accumulator 180. These main components of the cooling/heating system 100 can be connected to each other through a refrigerant line 2 so as to allow refrigerant to sequentially pass therethrough. In this manner, the refrigerant can circulate through all of the main components.

Among the above-mentioned components, the compressor 110, the external condenser 140, the second expansion valve 160, and the evaporator 170 are main components of an air-conditioning system and a refrigerant system for cooling of the vehicle interior. In the cooling mode, refrigerant compressed by the compressor 110 can be condensed in the external condenser 140 and then can be expanded in the second expansion valve 160. Thereafter, the low-temperature refrigerant expanded in the second expansion valve 160 can cool air-to-be-conditioned while passing through the evaporator 170.

In the components of the cooling/heating system 100, the compressor 110 can compress refrigerant suctioned from the accumulator 180 to a high-temperature and high-pressure state and transfer the compressed refrigerant through the refrigerant line 2, thereby enabling the refrigerant to circulate along the refrigerant line 2. The internal condenser 120 can be a heat exchanger configured to perform heat exchange between the refrigerant and the air-to-be-conditioned and can be a component configured to heat the vehicle interior.

The high-temperature and high-pressure refrigerant discharged from the compressor 110 can be supplied to the internal condenser 120 through the refrigerant line 2. Then, the high-temperature and high-pressure refrigerant supplied to the internal condenser 120 can perform, while passing through the inside of the internal condenser 120, heat exchange with air-to-be-conditioned passing through the periphery of the internal condenser 120.

The internal condenser 120 and the evaporator 170 can be installed in the air-conditioning case 1. Air-to-be-conditioned blown by an air-conditioning blower 12 can pass through the periphery of the internal condenser 120 while moving along the inside of the air-conditioning case 1. In this example, the air-to-be-conditioned can be heated by the high-temperature refrigerant passing through the inside of the internal condenser 120 and then can be discharged into the vehicle interior, thereby heating the vehicle interior.

The refrigerant that has exchanged heat with the air-to-be-conditioned in the internal condenser 120 can be supplied to the first expansion valve 130 through the refrigerant line 2. Here, the refrigerant may be expanded to a low-temperature and low-pressure state while passing through the first expansion valve 130. The first expansion valve 130 controlled by a controller 10 may be an electronic expansion valve capable of selectively expanding the refrigerant.

In an embodiment of the present disclosure, a separate refrigerant line (5, hereinafter referred to as a "branch line") can branch from the refrigerant line 2 on the inlet side of the evaporator 170, that is, the refrigerant line 2 between the receiver dryer 150 and the evaporator 170, and this branch line 5 can be connected to the refrigerant line 2 on the outlet side of the internal condenser 120, that is, the refrigerant line 2 between the internal condenser 120 and the external condenser 140.

The branch line 5 may be connected to the refrigerant line 2 on the outlet side of the internal condenser 120 via the first expansion valve 130, as shown in FIG. 1. In this example, the first expansion valve 130 may be an electronic three-way expansion valve, the opening state of which is controlled by the controller 10.

The refrigerant passing through the first expansion valve 130 can be supplied to the external condenser 140 through which heat exchange between refrigerant and air is performed. The refrigerant supplied to the external condenser 140 can perform, while passing through the inside of the external condenser 140, heat exchange with air passing through the periphery of the external condenser 140.

Here, the air can be outside air (outdoor air) suctioned by a cooling fan 11, and the low-temperature and low-pressure refrigerant expanded in the first expansion valve 130 may receive, while passing through the inside of the external condenser 140, heat from the outside air passing through the periphery of the external condenser 140.

In this manner, the first expansion valve 130 and the external condenser 140 may be used as components capable of implementing a heat pump operation in which heat is received from the outside air and is supplied and moved through the refrigerant of the refrigerant system.

In an embodiment of the present disclosure, the internal condenser 120 can be connected to the refrigerant line 2 on the outlet side of the compressor 110 and can serve as an indoor heat exchanger configured to perform heat exchange between the refrigerant flowing through the inside of the air-conditioning case 1 and air-to-be-conditioned, and the external condenser 140 can serve as an outdoor heat exchanger configured to perform heat exchange between the refrigerant flowing through the inside of the external condenser and the outside air (outdoor air) suctioned by the cooling fan 11.

The external condenser 140 may serve as, in the cooling mode, a condenser (radiator) configured to discharge heat of the refrigerant to the outside air (heat dissipation to the outside air) and may serve as, in the heating mode, the evaporator 170 configured to receive heat of the outside air through the refrigerant (heat absorption from the outside air).

In an embodiment of the present disclosure, the refrigerant passing through the external condenser 140 can be supplied to the receiver dryer 150. Here, the receiver dryer 150 can remove moisture from the refrigerant and then supply the refrigerant from which moisture has been removed back to the external condenser 140.

In a vehicle thermal management device according to an embodiment of the present disclosure, it can be possible to perform selective heat exchange between the refrigerant inside the receiver dryer 150 and coolant discharged from the radiator 227. To this end, the heat exchange module 240 to be described below can be installed in the receiver dryer 150.

The refrigerant that has passed through the receiver dryer 150 can be discharged again to the refrigerant line 2 through the external condenser 140 and then can be supplied to the second expansion valve 160 along the refrigerant line 2. In this example, the second expansion valve 160 can expand the refrigerant to a low-temperature and low-pressure state.

The second expansion valve 160 may be a mechanical expansion valve or an electronic expansion valve, the operation of which can be controlled by the controller 10. Here, the electronic expansion valve may selectively expand the refrigerant by the controller 10.

The refrigerant that has passed through the second expansion valve 160 can be supplied to the evaporator 170 installed inside the air-conditioning case 1 through the refrigerant line 2. When the low-temperature and low-pressure refrigerant expanded by the second expansion valve 160 is supplied to the evaporator 170, heat exchange may be performed between the low-temperature and low-pressure refrigerant passing through the inside of the evaporator 170 and air-to-be-conditioned passing through the periphery of the evaporator 170.

In this manner, the air-to-be-conditioned blown into the inside of the air-conditioning case 1 by the air-conditioning blower 12 may be cooled by the refrigerant passing through the inside of the evaporator 170 while passing through the periphery of the evaporator 170. In this example, conditioned air cooled by the refrigerant can be discharged into the vehicle interior, thereby cooling the vehicle interior.

The refrigerant that has passed through the evaporator 170 can flow to the accumulator 180, and gas-liquid separation of the refrigerant can be performed in the accumulator 180. The accumulator 180 can be installed on the refrigerant line 2 on the inlet side of the compressor 110, that is, the refrigerant line 2 between the evaporator 170 and the compressor 110, based on a refrigerant circulation path. The accumulator 180 can serve to improve efficiency and durability of the compressor 110 by supplying only gaseous refrigerant to the compressor 110 through gas-liquid separation.

As a result, the refrigerant of the cooling/heating system 100 can sequentially pass through the compressor 110, the internal condenser 120, the first expansion valve 130, the external condenser 140, the receiver dryer 150, and the external condenser 140 while circulating along the refrigerant line 2. Thereafter, the refrigerant can pass through the second expansion valve 160 and the evaporator 170 along the refrigerant line 2 and then move to the accumulator 180 to circulate through the refrigerant system again. Alternatively, the refrigerant can move from the refrigerant line 2 to the branch line 5 and then move from the branch line 5 to the refrigerant line 2 again to circulate through the refrigerant system.

A chiller refrigerant line 3 can branch from the refrigerant line 2 on the outlet side of the external condenser 140, that is, the refrigerant line 2 between the external condenser 140 and the evaporator 170, and the chiller refrigerant line 3 can be connected to the refrigerant line 2 on the inlet side of the accumulator 180.

A third expansion valve 191 serving as an expansion valve for a chiller and a chiller 192 can be installed on the chiller refrigerant line 3. Refrigerant that has moved from the refrigerant line 2 to the chiller refrigerant line 3 can pass through the third expansion valve 191, and a refrigerant bypass line 4 can branch from the chiller refrigerant line 3 via the third expansion valve 191. The refrigerant bypass line 4 can be connected to and combined with the chiller refrigerant line 3 on the outlet side of the chiller 192 or the refrigerant line 2 on the inlet side of the accumulator 180.

The third expansion valve 191 may be an electronic expansion valve in the form of a three-way valve, the opening state of which can be controlled by the controller 10. The third expansion valve 191 may allow, depending on the opening state thereof, the refrigerant that has moved from the refrigerant line 2 to the chiller refrigerant line 3 to flow to the refrigerant bypass line 4 without expansion of the refrigerant, or to flow to the chiller 192 after expanding the refrigerant to a low-temperature and low-pressure state.

In this manner, the third expansion valve 191 and the refrigerant bypass line 4 can be components configured not only to selectively expand the refrigerant, but also to allow the refrigerant to selectively bypass the chiller 192.

The refrigerant bypassing the chiller 192 without passing therethrough can pass through the third expansion valve 191 without expansion thereof, move to the refrigerant bypass line 4, and then flow to the accumulator 180.

The chiller 192 can be provided to allow a cooling medium to pass therethrough. Here, examples of the cooling medium can include refrigerant that has passed through the third expansion valve 191, coolant (battery coolant) of a battery thermal management system 210, and coolant (PE coolant) of a power electronics (PE) thermal management system 220. Accordingly, heat exchange between the cooling media passing through the inside of the chiller 192 may be performed.

The component thermal management system 200 can include the battery thermal management system 210 and the PE thermal management system 220 configured to circulate coolant, respectively. The battery thermal management system 210 can be configured to control and manage the temperature of the battery 212 and can have a configuration in which a battery coolant line 6 connects a battery coolant passage part 213 provided in the battery 212 to the chiller 192 so as to allow battery coolant to circulate there along. In the battery thermal management system 210, a water pump 211 (second water pump) can be installed on the battery coolant line 6.

The PE thermal management system 220 can be configured to control and manage the temperature of the power electronics system 225 (hereinafter referred to as "PE system") and can have a configuration in which a PE coolant passage part 226 provided in components of the PE system 225, the chiller 192, and the radiator 227 can be connected to each other through a PE coolant line 7 so as to allow PE coolant to circulate along the PE coolant passage part 226, the chiller 192, and the radiator 227. Here, in the PE thermal management system 220, a water pump 221 (first water pump) can be installed on the PE coolant line 7.

The components of the PE system 225 may include an inverter and a motor mounted in an electric vehicle. Specifically, the components may include at least one of a front wheel motor and a rear wheel motor each serving as a driving device, a front wheel inverter configured to drive and control the front wheel motor, and a rear wheel inverter configured to drive and control the rear wheel motor.

Here, the front wheel motor can be a motor connected to front wheels of the vehicle so as to transmit power thereto and configured to drive the front wheels, and the rear wheel motor can be a motor connected to rear wheels of the vehicle so as to transmit power thereto and configured to drive the rear wheels.

In the PE thermal management system 220, the PE coolant line 7 on the outlet side of the water pump 221 can be connected to the chiller 192, and a heater coolant line 8 branching from the PE coolant line 7 on the outlet side of the water pump 221 and the inlet side of the chiller 192 can be connected to the PE coolant line 7 on the outlet side of the chiller 192.

The water heater 223 can be installed in the middle of the heater coolant line 8, and the PE coolant flowing along the heater coolant line 8 can pass through the water heater 223. Accordingly, when the water heater 223 is in operation, the PE coolant flowing along the heater coolant line 8 can be heated while passing through the water heater 223.

A first valve 222 configured to control the flow of the PE coolant can be installed at a branch point at which the heater coolant line 8 branches from the PE coolant line 7 on the outlet side of the water pump 221. Here, the first valve 222 may be an electronic three-way valve, the opening state of which can be controlled by the controller 10.

A connection line 9 can branch from the PE coolant line 7 between the PE coolant passage part 226 provided in the component of the PE system 225 and the water pump 221, and the connection line 9 branching therefrom can be connected to the heater coolant line 8.

A second valve 224 configured to control the flow of the PE coolant can be installed at a location where the connection line 9 branches from the PE coolant line 7. Here, the second valve 224 may be an electronic three-way valve, the opening state of which can be controlled by the controller 10.

A separate PE coolant line connecting the PE coolant line 7 on the inlet side of the PE coolant passage part 226 (which may be the outlet side depending on the coolant passage direction) to the PE coolant line 7 on the outlet side of the PE coolant passage part 226 can branch from the PE coolant line 7. The separate PE coolant line 7 can be connected to a coolant inlet 228 of the radiator 227 and a coolant outlet 244 of the heat exchange module 240 to be described later.

A third valve 230 configured to control the flow of the PE coolant can be installed at a branch point at which the separate PE coolant line connected to the radiator 227 branches from the PE coolant line 7 on the inlet side of the PE coolant passage part 226.

The third valve 230 may be an electronic three-way valve, the opening state of which can be controlled by the controller 10. Depending on the opening state of the third valve 230, the PE coolant may not flow to the PE coolant passage part 226 and the PE coolant line 7 connected thereto, or the PE coolant may selectively flow to the radiator 227.

That is, when the opening state of the third valve 230 is controlled, all of the coolant circulating through the PE coolant passage part 226 and the chiller 192 may flow only to the PE coolant passage part 226 of the PE system 225 without passing through the radiator 227. Alternatively, all of the coolant may flow only to the radiator 227 without passing through the PE coolant passage part 226.

Alternatively, when the opening state of the third valve 230 is controlled, all of the coolant circulating through the PE coolant passage part 226 and the chiller 192 may flow to the heater coolant line 8 and pass through the water heater 223.

When the opening state of the third valve 230 is controlled, the controlled amount of coolant circulating through the PE coolant passage part 226 and the chiller 192 may be distributed and introduced into the PE coolant passage part 226 of the PE system 225, the radiator 227, and the water heater 223.

The heat exchange module 240 can be connected to the coolant line 7 (PE coolant line) on the outlet side of the radiator 227 such that the coolant may enter and exit through the coolant line 7, and the heat exchange module 240 can be installed in the receiver dryer 150. The heat exchange module 240 can be a component configured to enable heat exchange between the refrigerant inside the receiver dryer 150 and the coolant discharged from the radiator 227.

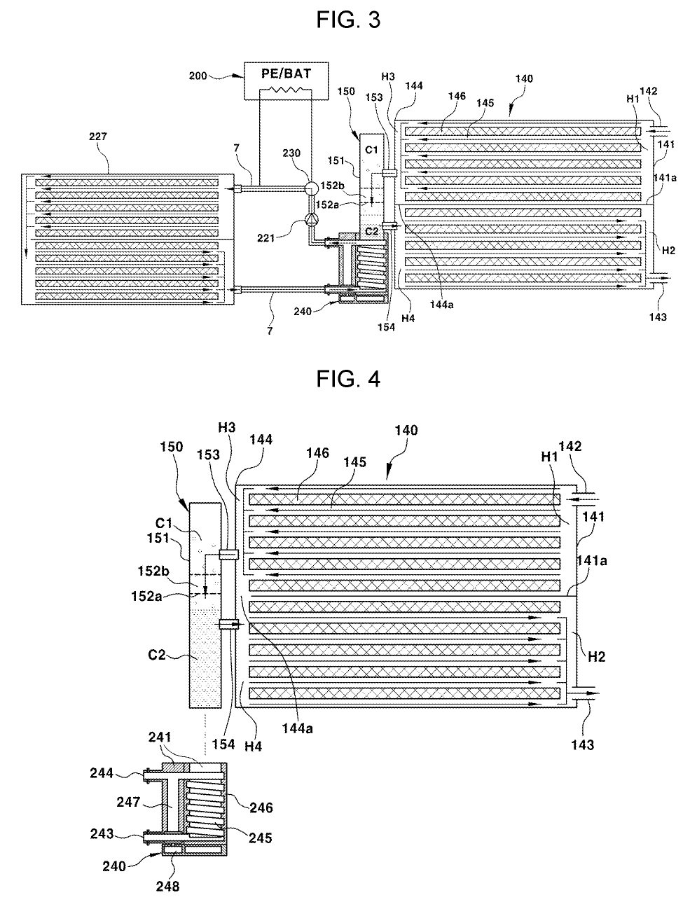

FIG. 3 is a diagram showing a configuration of a vehicle thermal management device according to an embodiment of the present disclosure. FIG. 4 is a diagram showing the receiver dryer and the heat exchange module in a state of being separated from the vehicle thermal management device according to an embodiment of the present disclosure.

As shown in the drawing, the vehicle thermal management device according to an embodiment of the present disclosure can include the radiator 227 configured to perform heat exchange between PE coolant passing through the inside thereof and air passing through the periphery thereof, the condenser 140 (external condenser) configured to perform heat exchange between refrigerant passing through the inside thereof and air passing through the periphery thereof, the receiver dryer 150 configured to remove moisture from the refrigerant passing through the condenser 140, and the heat exchange module 240 configured to selectively perform heat exchange between the refrigerant of the receiver dryer 150 and the PE coolant discharged from the radiator 227.

In the vehicle thermal management device, the radiator 227 and the cooling fan 11 can form a cooling module of a vehicle and serve as a heat exchanger configured to perform heat exchange between coolant (PE coolant) and air. In the cooling module, the outside air (outdoor air) suctioned by the cooling fan 11 can perform heat exchange with coolant passing through the inside of the radiator 227 while passing through the periphery of the radiator 227.

The coolant that has cooled the battery 212 and the PE system 225 can pass through the inside of the radiator 227. To this end, the coolant line (PE coolant line) of the component thermal management system 200 can be connected to the radiator.

A connection relationship between the radiator 227 and the component thermal management system 200 is shown in FIG. 1. The water pump 221 shown in FIG. 3 is a water pump of the PE thermal management system 220, and the three-way valve 230 shown in FIG. 3 is the third valve described above.

Referring to FIG. 3, the coolant inlet 228 of the radiator 227 can be connected to the coolant line 7 (PE coolant line) of the component thermal management system 200, and a coolant outlet 229 of the radiator 227 can be connected to a coolant inlet 243 of the heat exchange module 240 through the coolant line 7.

In the vehicle thermal management device of an embodiment, the condenser 140 can be an external condenser serving as an outdoor heat exchanger and can be configured to include a first header tank 141, a second header tank 144, a tube 145, and a fin 146. The first header tank 141 and the second header tank 144 can be arranged in parallel with each other in a state of being spaced apart from each other by a predetermined distance, and each of the first header tank and the second header tank can have an internal space formed therein and configured to allow refrigerant to pass therethrough.

The tube 145 through which refrigerant may flow horizontally can connect the first header tank 141 to the second header tank 144, in which the first header tank 141 and the second header tank 144 can be spaced apart from each other. The tube 145 can have opposite ends respectively fixed to the first header tank 141 and the second header tank 144. An internal space of the tube 145, which can serve as a refrigerant flow path, can communicate with the internal spaces of the first header tank 141 and the second header tank 144, thereby enabling the refrigerant to flow through the internal spaces.

In a typical condenser, the plural tubes 145 are installed in parallel with each other in a state of being vertically spaced apart from each other between the first header tank 141 and the second header tank 144. Accordingly, the refrigerant may flow between the first header tank 141 and the second header tank 144 through the plurality of parallel tubes 145 installed in parallel with each other. In this structure, the fins 146 can be respectively interposed between the plurality of tubes 145 so as to increase a heat transfer area.

A condenser having two flow paths is shown in FIG. 3, and a refrigerant flow path inside the condenser 140 is shown by an arrow. The first header tank 141 of the condenser 140 can be provided with an inlet 142 through which refrigerant can be introduced, and an outlet 143 through which refrigerant can be discharged. Partition walls 141a and 144a can be installed in the header tanks 141 and 144 so as to partition the internal space into upper chambers H1 and H3 and lower chambers H2 and H4.

The receiver dryer 150 can be connected to the condenser 140. Here, an inner space of a housing 151 of the receiver dryer 150 can be partitioned into an upper chamber C1 and a lower chamber C2 by a strainer 152a and a desiccant 152b. The inlet 142 of the condenser 140 can be installed in the upper chamber H1 partitioned by the partition wall 141a in the first header tank 141, and the outlet 143 of the condenser 140 can be installed in the lower chamber H2 partitioned by the partition wall 141a in the first header tank 141.

In the condenser 140, the upper chamber H3 of the second header tank 144 can be connected to the upper chamber C1 of the receiver dryer 150 through a connection passage 153, thereby enabling the refrigerant to flow through the upper chamber H3 and the upper chamber C1 with the connection passage 35 interposed therebetween. The lower chamber H4 of the second header tank 144 can be connected to the lower chamber C2 of the receiver dryer 150, thereby enabling the refrigerant to flow through the lower chamber H4 and the lower chamber C2 with a connection passage 154 interposed therebetween.

In this structure, when the refrigerant is introduced through the inlet 142 of the condenser 140, the refrigerant can move horizontally from the upper chamber H1 of the first header tank 141 to the upper chamber H3 of the second header tank 144 through the tube 145, thereby forming a first refrigerant flow path.

The refrigerant that has moved to the upper chamber H3 of the second header tank 144 can move to the upper chamber C1 of the receiver dryer 150 through the connection passage 153. Thereafter, the refrigerant can pass through the strainer 152a and the desiccant 152b and move to the lower chamber C2 of the receiver dryer 150.

The refrigerant that has moved to the lower chamber C2 of the receiver dryer 150 can move to the lower chamber H4 of the second header tank 144 through the connection passage 154, and the refrigerant that has moved to the lower chamber H4 of the second header tank 144 can move horizontally to the lower chamber H2 of the first header tank 141 through the tube 145, thereby forming a second refrigerant flow path. In this manner, the refrigerant that has moved to the first header tank 141 can be discharged to the outside through the outlet 143 of the condenser 140.

As shown in FIG. 3, the condenser 140 can have two refrigerant flow paths formed therein, but an embodiment of the present disclosure is not necessarily limited thereto. For example, it can be also possible to provide the condenser 140 having three refrigerant flow paths formed therein or the condenser 140 having four refrigerant flow paths formed therein.

In an embodiment of the present disclosure, the refrigerant flowing into the first header tank 141 through the inlet 142 of the condenser 140 may be in the high-temperature and high-pressure state, and the refrigerant discharged from the first header tank 141 through the outlet 143 of the condenser may be in the low-temperature and high-pressure state.

The reason for this is that, while the high-temperature refrigerant flows into the first header tank 141 through the inlet 142 moves to the second header tank 144 and then passes through the receiver dryer 150, the refrigerant can be cooled by coolant (PE coolant) passing through the heat exchange module 240, in which the coolant has been discharged from the radiator 227, and the low-temperature refrigerant that has completed heat exchange with the coolant can move from the second header tank 144 to the first header tank 141 and then can be discharged through the outlet 143.

In an embodiment of the present disclosure, the receiver dryer 150 can perform a function of removing moisture from the refrigerant using the desiccant 152b and also perform a function of separating the refrigerant inside the housing 151 into gaseous refrigerant and liquid refrigerant.

In the housing 151 of the receiver dryer 150, the lower chamber C2 can be mainly filled with liquid refrigerant, and the heat exchange module 240 for heat exchange with coolant may be installed in the lower chamber C2 of the receiver dryer 150. Accordingly, heat exchange may be performed between the coolant passing through the heat exchange module 240 and the liquid refrigerant inside the receiver dryer 150.

In an embodiment of the present disclosure, the housing 151 of the receiver dryer 150 may be manufactured using a metal material having reliable heat transfer, such as an aluminum alloy containing aluminum (Al) having high thermal conductivity. Accordingly, it can be possible to ensure that heat exchange is reliably performed between the refrigerant filling the inside of the housing 151 of the receiver dryer 150 and the coolant passing through a heat exchange part 246 outside the housing 151.

FIG. 3 is a diagram showing a state in which the heat exchange module 240 can be coupled to the receiver dryer 150. FIG. 4 is a diagram showing a state in which the heat exchange module 240 can be separated from the receiver dryer 150.

As shown in the drawings, the heat exchange module 240 may be installed outside the receiver dryer 150 and may perform, while the coolant that has passed through the heat exchange module 240 passes through the periphery of the receiver dryer 150, heat exchange with the liquid refrigerant filling the inside of the receiver dryer 150.

Specifically, the heat exchange module 240 can include the heat exchange part 246 provided to allow coolant (PE coolant) discharged from the radiator 227 to pass therethrough and configured to perform heat exchange between the coolant and the refrigerant inside the receiver dryer 150, a bypass flow path part 247 configured to allow the coolant discharged from the radiator 227 to bypass the heat exchange part 246 such that the coolant does not pass through the heat exchange part 246, and a valve device 248 configured to control a flow of the coolant so as to allow the coolant discharged from the radiator 227 to selectively flow through the heat exchange part 246 or the bypass flow path part 247.

In an embodiment of the present disclosure, the heat exchange module 240 can further include a main body block 241. The main body block 241 can include a coolant inlet 243 into which the coolant discharged from the radiator 227 can be introduced, and a coolant outlet 244 through which the coolant that has selectively passed through one of the heat exchange part 246 and the bypass flow path part 247 can be discharged. The coolant inlet 243 of the heat exchange module 240 can be connected to the coolant outlet 229 of the radiator 227 through the coolant line 7 (PE coolant line), and the coolant outlet 244 of the heat exchange module 240 can be connected to the coolant line 7 on the water pump side such that the discharged coolant may flow toward the component thermal management system 200, more specifically, the water pump 221 of the PE thermal management system 220 in FIG. 1.

Referring to FIG. 3, the coolant inlet 243 can be formed at a lower portion of the main body block 241, and the coolant outlet 244 can be formed at an upper portion of the main body block 241. In the heat exchange module 240, the heat exchange part 246 can be provided on one side of the main body block 241, and the bypass flow path part 247 can be provided on the other side of the main body block 241. In this example, the valve device 248 may be arranged at a lower portion of the main body block 241.

In an embodiment of the present disclosure, the bypass flow path part 247 of the heat exchange module 240 may be a flow path formed to penetrate the inside of the main body block 241 and may be provided as a flow path structure formed to directly connect the coolant inlet 243 to the coolant outlet 244 in the main body block 241.

Referring to FIG. 3, the bypass flow path part 247 can be formed to vertically penetrate the inside of the main body block 241 so as to directly connect the coolant inlet 243 and the coolant outlet 244 in the main body block 241.

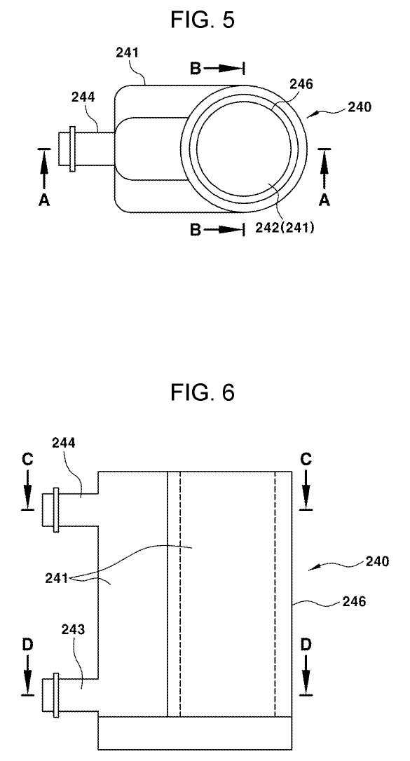

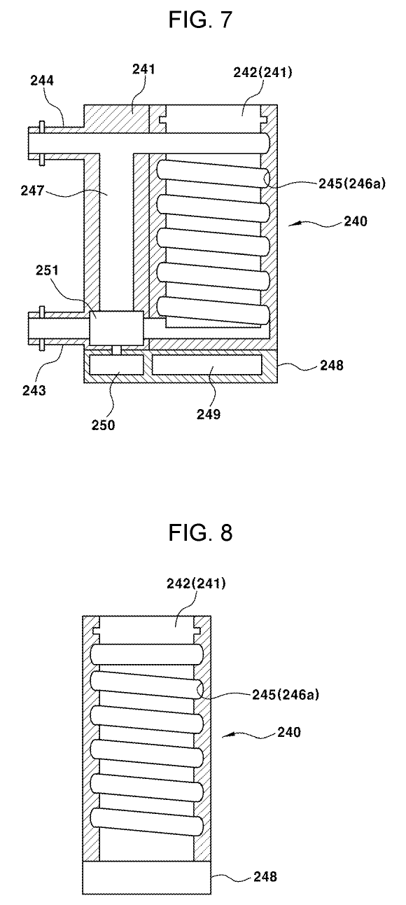

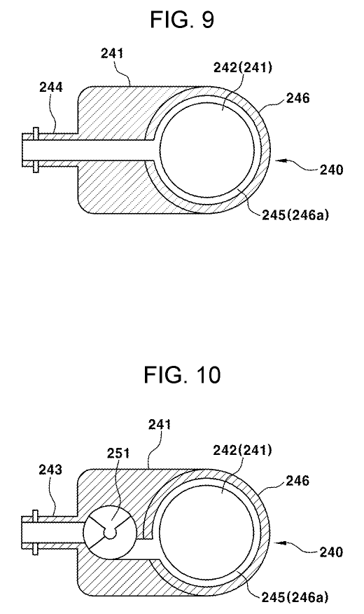

FIG. 5 is a plan view of the heat exchange module 240 in an embodiment of the present disclosure. FIG. 6 is a side view of the heat exchange module 240 in an embodiment of the present disclosure. FIG. 7 is a cross-sectional view taken along line "A-A" in FIG. 5. FIG. 8 is a cross-sectional view taken along line "B-B" in FIG. 5. FIG. 9 is a cross-sectional view taken along line "C-C" in FIG. 6. FIG. 10 is a cross-sectional view taken along line "D-D" in FIG. 6.

In an embodiment of the present disclosure, the heat exchange part 246 can be provided to perform heat exchange between coolant passing through the inside thereof and liquid refrigerant stored in the receiver dryer 150, and the entire heat exchange part 246 including a coolant flow path 246a may be installed on the outside of the receiver dryer 150.

In an embodiment of the present disclosure, the heat exchange part 246 may be formed to include the coolant flow path 246a that contacts the outer surface of the housing 151 of the receiver dryer 150. Specifically, the heat exchange part 246 may be configured to form the coolant flow path 246a having a coil shape that contacts the outer surface of the housing 151 of the receiver dryer 150 and spirally surrounds the periphery of the housing 151 of the receiver dryer 150.

In an embodiment of the present disclosure, the coolant flow path 246a of the heat exchange part 246 may be formed to be disposed around the lower chamber C2 in which the liquid refrigerant is mainly stored in the housing 151 of the receiver dryer 150.

In an embodiment of the present disclosure, to improve assemblability between the heat exchange part 246 and the receiver dryer 150, it can be possible to apply an insertion-type assembly structure in which a lower portion of the receiver dryer 150 can be inserted into the main body block 241 of the heat exchange part 246 for assembly therebetween.

That is, an accommodation part 242 into which the lower portion of the housing 151 of the receiver dryer 150 may be vertically inserted downwards is formed in the main body block 241. Accordingly, the lower portion of the housing 151 of the receiver dryer 150 can be inserted into the accommodation part 242 of the main body block 241, thereby assembling the housing with the heat exchange part 246.

In the main body block 241, the accommodation part 242 can be formed to have a size and shape such that the outer surface of the receiver dryer 150 and the inner surface of the accommodation part 242 can be joined to each other in a state in which the receiver dryer 150 is inserted into the accommodation part 242.

For example, the housing 151 of the receiver dryer may be formed to have a cylindrical shape. In this example, when the housing 151 of the receiver dryer 150 is inserted into the accommodation part 242 of the main body block 241, an inner surface of the accommodation part 242 of the main body block 241 and an outer surface of the housing 151 of the receiver dryer 150 may have respective sizes allowing the inner surface and the outer surface to be in close contact with each other.

Here, a flow path groove 245 having a predetermined depth may be formed in the inner surface of the accommodation part 242, in which the flow path groove spirally can extend so as to connect the coolant inlet 243 of the main body block 241 to the coolant outlet 244 of the main body block 241.

In this example, in a state in which the main body block 241 and the housing 151 of the receiver dryer 150 are assembled with each other, the flow path groove 245 may be sealed by the outer surface of the housing 151 of the receiver dryer 150, thereby forming the long spiral coolant flow path 246a.

In this manner, when the housing 151 of the receiver dryer 150 is simply inserted into the accommodation part 242 of the main body block 241, it can be possible to form, using the flow path groove 245 of the accommodation part 242, the coolant flow path 246a between the main body block 241 of the thermal management module and the housing 151 of the receiver dryer 150 in a state in which the coolant flow path can be disposed around the housing 151 of the receiver dryer 150 while contacting the outer surface of the housing 151 of the receiver dryer 150.

In this example, in a state in which the receiver dryer 150 manufactured from a metal material having excellent thermal conductivity, such as aluminum, is assembled with the main body block 241 of the heat exchange module 240, when coolant discharged from the radiator 227 is supplied to the coolant flow path 246a of the heat exchange part 246, the coolant can pass through the coolant flow path 246a of the heat exchange part 246 while spirally flowing around the receiver dryer 150. At such flow path, the coolant may absorb heat from the refrigerant of the receiver dryer 150 through the housing 151.

The coolant supplied from the radiator 227 to the heat exchange module 240 can be the coolant that has completed heat exchange with the air in the radiator, that is, the coolant that has discharged heat to the air. Therefore, when supplied to the heat exchange part 246 of the heat exchange module 240, the coolant may absorb heat from the refrigerant.

In this manner, in an embodiment of the present disclosure, the receiver dryer 150 may be assembled with the heat exchange module 240 by being inserted into the heat exchange module 240 without changing the structure or shape of the condenser 140. In this example, there is no need to install a separate heat exchanger or provide a coolant line inside the receiver dryer.

The valve device 248 of the heat exchange module 240 can be configured to allow the coolant inlet 243 of the main body block 241 to selectively communicate with one of the heat exchange part 246 and the bypass flow path part 247, or to be blocked from both the heat exchange part 246 and the bypass flow path part 247. The valve device 248 may be formed at the lower portion of the main body block 241.

In an embodiment of the present disclosure, the valve device 248 can include a valve body 251 disposed at a branching position from which the bypass flow path part 247 and the coolant flow path 246a of the heat exchange part 246 branch in the main body block 241, in which the valve body can be configured to, depending on the rotated state thereof, allow the coolant inlet 243 to communicate with a selected one of the bypass flow path part 247 and the coolant flow path 246a of the heat exchange part 246 or to be blocked from the selected one, an actuator 250 configured to rotate the valve body 251, and a valve controller 249 configured to control the operation of the actuator 250.

In the valve device 248, the actuator 250 configured to rotate the valve body 251 may be a motor. The valve controller 249 can be communicably connected to the controller 10 of the thermal management system.

The controller 10 of the thermal management system can transmit a control signal to the valve controller 249 so as to control the operation of the actuator 250, and the valve controller 249 can control the operation of the actuator 250 in response to the control signal received from the controller 10 of the thermal management system. Thereby, the rotation position of the valve body 251 may be controlled, and the opening state of the valve device 248 may be controlled.

In an embodiment of the present disclosure, the valve device 248 can be controlled in a heat exchange mode in which the bypass flow path part 247 can be closed and the coolant flow path 246a of the heat exchange part 246 can be opened, a bypass mode in which the bypass flow path part 247 can be opened and the coolant flow path 246a of the heat exchange part 246 can be closed, and a coolant blocking mode in which both the bypass flow path part 247 and the coolant flow path 246a of the heat exchange part 246 can be closed.

In an embodiment of the present disclosure, when one of the operation modes of the heat exchange module 240, that is, the heat exchange mode, the bypass mode, and the coolant blocking mode, is selected, the controller 10 of the thermal management system can output a control signal to rotate the valve body 251 such that the valve body can reache a predetermined rotation position of the selected mode (a "first rotation position", a "second rotation position", and a "third rotation position" to be described below).

Accordingly, the valve controller 249 receiving the control signal can control the operation of the actuator 250 so as to rotate the valve body 251. In this manner, the valve body can reache the rotation position corresponding to the selected mode.

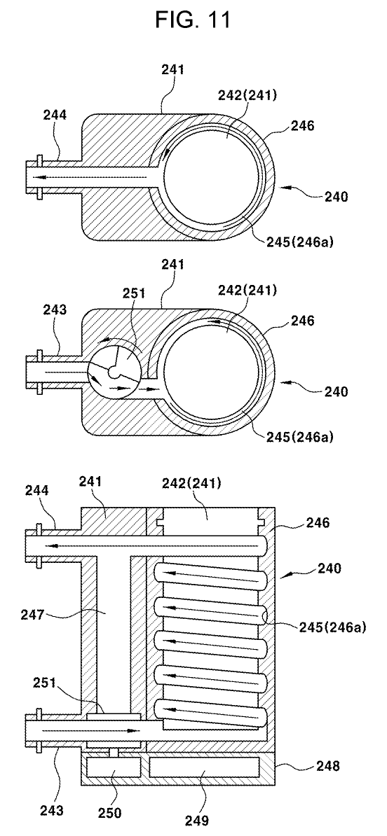

FIGS. 11 to 13 are diagrams each showing the control of the valve device and the coolant flow state depending on the operation mode of the heat exchange module in an embodiment of the present disclosure.

FIG. 11 is a diagram showing the heat exchange mode in which heat exchange is performed between the refrigerant inside the receiver dryer 150 and the coolant discharged from the radiator 227. Referring to FIG. 11, it may be seen that the bypass flow path part 247 is closed and the coolant flow path 246a of the heat exchange part 246 is opened.

In this manner, in the heat exchange mode, the operation of the valve device 248 can be controlled such that the valve body 251 is rotated to a position at which the bypass flow path part 247 is closed and the coolant flow path 246a of the heat exchange part 246 is opened.

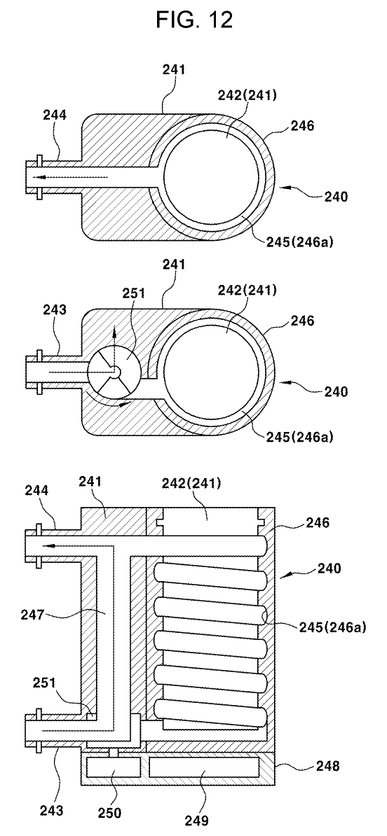

FIG. 12 is a diagram showing the bypass mode in which the coolant discharged from the radiator 227 bypasses the heat exchange part 246 such that heat exchange between the refrigerant and the coolant present in the receiver dryer 150 is not performed.

FIG. 12 shows a state in which the bypass flow path part 247 is opened and the coolant flow path 246a of the heat exchange part 246 is closed. In this manner, in the bypass mode, the operation of valve device 248 can be controlled such that the valve body 251 is rotated to a position at which the bypass flow path part 247 is opened and the coolant flow path 246a of the heat exchange part 246 is closed.

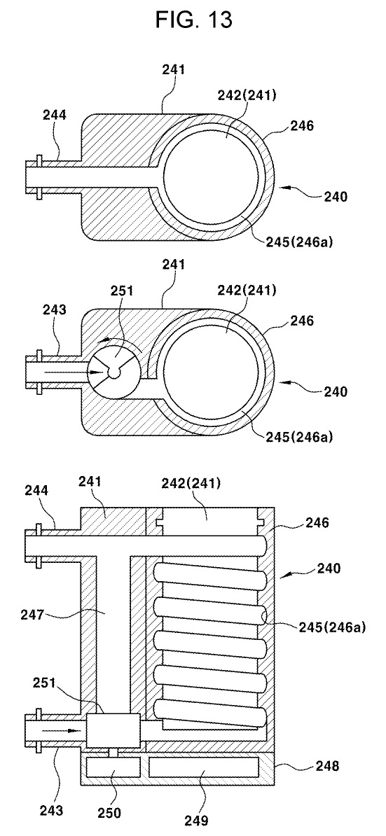

FIG. 13 is a diagram showing the coolant blocking mode in which coolant is blocked from passing through the bypass flow path part 247 and the heat exchange module 240. Referring to FIG. 13, it may be seen that the bypass flow path part 247 and the coolant flow path 246a of the heat exchange part 246 are both closed.

In this manner, in the coolant blocking mode, the operation of the valve device 248 can be controlled such that the valve body 251 is rotated to a position at which both the bypass flow path part 247 and the coolant flow path 246a of the heat exchange part 246 are closed.

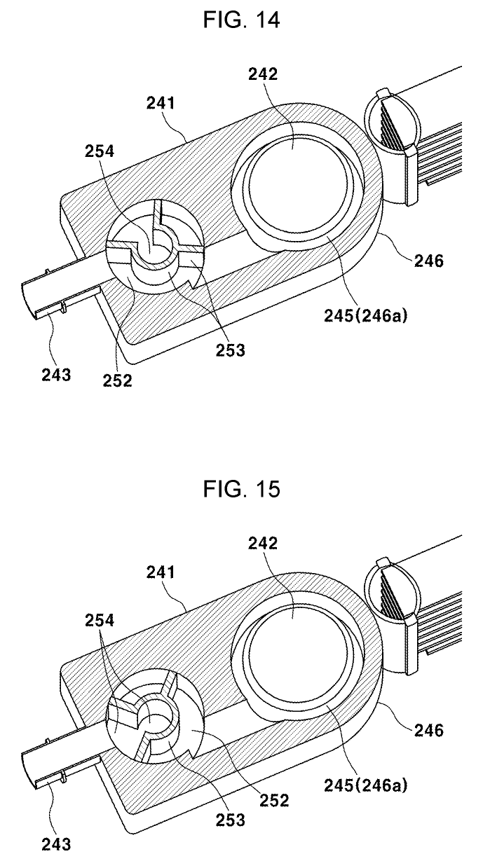

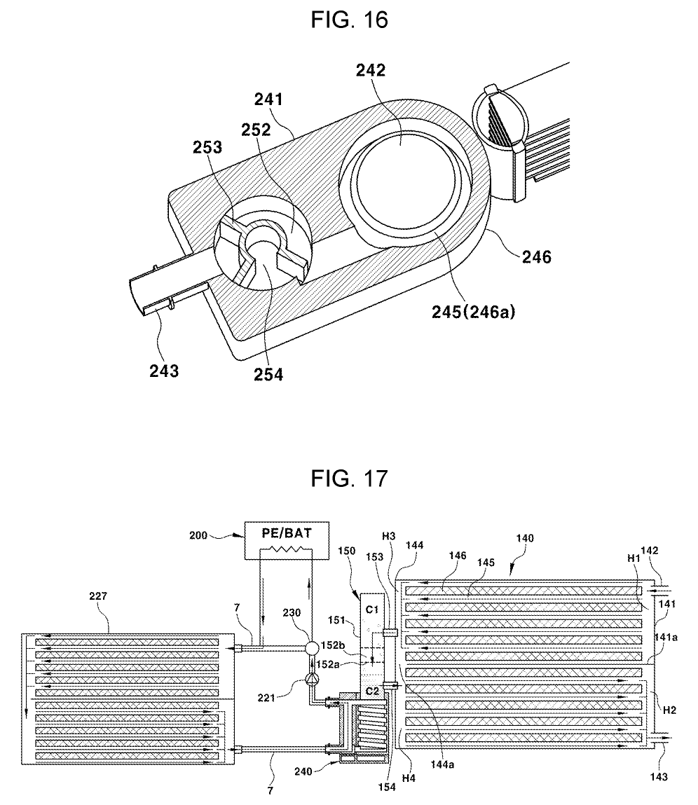

FIGS. 14 to 16 are perspective views each showing the valve body rotation position and the valve device opening state depending on the operation mode of the heat exchange module in an embodiment of the present disclosure, and are cross-sectional perspective views taken along the line "D-D" of FIG. 6. FIG. 14 shows the heat exchange mode, FIG. 15 shows the bypass mode, and FIG. 16 shows the coolant blocking mode.

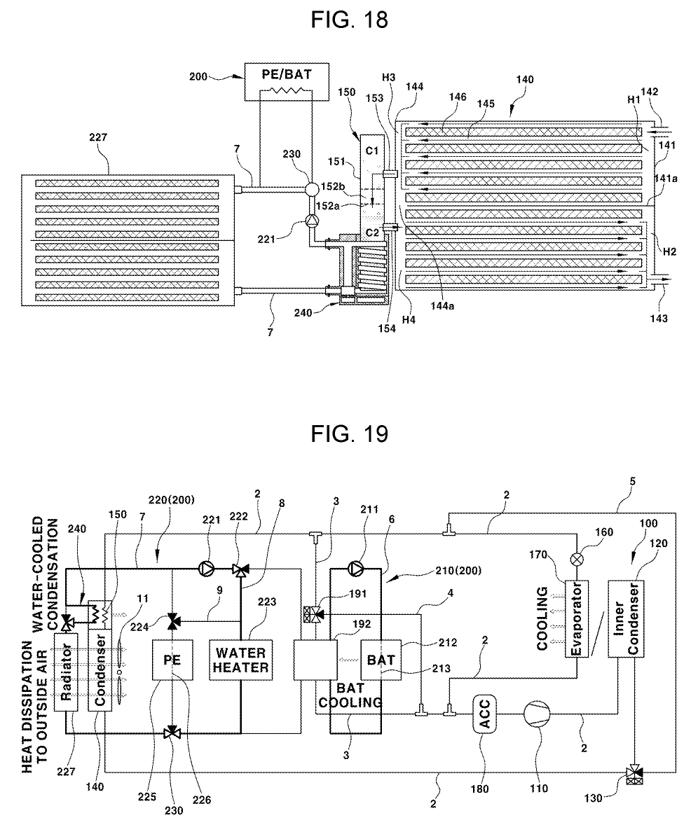

FIGS. 3, 17, and 18, are diagrams each showing the flow of coolant and refrigerant in the vehicle thermal management device of an embodiment of the present disclosure. Here, in each of the diagrams, arrows indicate the flow paths of coolant and refrigerant. In FIG. 3, arrows indicate the flow paths of coolant and refrigerant in the heat exchange mode, in FIG. 17, arrows indicate the flow paths of coolant and refrigerant in the bypass mode, and in FIG. 18, arrows indicate the flow paths of refrigerant in the coolant blocking mode.

As shown in the drawings, the valve body 251 can have a first flow path part 252 formed therein and configured to allow, at the first rotation position of the valve body, the coolant inlet 243 of the heat exchange module 240 and the coolant flow path 246a to communicate with each other, and a blocking wall 253 formed therein and configured to cause the coolant inlet 243 to be blocked from the bypass flow path part 247 at the first rotation position.

The valve body 251 can have a second flow path part 254 formed therein and configured to allow, at the second rotation position of the valve body, the coolant inlet 243 of the heat exchange module 240 and the bypass flow path part 247 to communicate with each other, and the blocking wall 253 formed to cause the coolant inlet 243 of the heat exchange module 240 to be blocked from the coolant flow path 246a of the heat exchange part 246 at the second rotation position.

To close both of the coolant flow path 246a of the heat exchange part 246 and the bypass flow path part 247 by the valve body 251, the valve body 251 can have the blocking wall 253 formed therein and configured to cause the coolant inlet 243 of the heat exchange module 240 to be simultaneously blocked from the coolant flow path 246a of the heat exchange part 246 and the bypass flow path part 247 at the third rotation position of the valve body 251.

The first rotation position can be a rotation position of the valve body 251 at which the heat exchange module 240 can be set to the heat exchange mode, the second rotation position can be a rotation position of the valve body 251 at which the heat exchange module 240 can be set to the bypass mode, and the third rotation position can be a rotation position of the valve body 251 at which the heat exchange module 240 can be set to the coolant blocking mode.

The coolant flow state according to the operation mode of the heat exchange module 240 will be described. As shown in FIG. 3, in the heat exchange mode, because the coolant flow path 246a of the heat exchange part 246 is opened, the coolant cooled by air in the radiator 227 can move to the heat exchange module 240 and pass through the coolant flow path 246a of the heat exchange part 246.

At this mode, the coolant can exchange heat with the refrigerant in the receiver dryer 150 while passing through the coolant flow path 246a of the heat exchange part 246. Here, when the heat of the refrigerant is transferred to the coolant, the pressure of the refrigerant system may be lowered such that additional subcooling can be secured.

In the bypass mode, because the bypass flow path part 247 is opened, the coolant from the radiator 227 can pass through the bypass flow path part 247 of the heat exchange module 240. Here, because the coolant bypasses the heat exchange part 246 configured to perform heat exchange with the receiver dryer 150, the coolant can be discharged directly from the heat exchange module 240 without heat exchange with the refrigerant.

The coolant discharged from the heat exchange module 240 can be then moved to the component thermal management system 200. In this manner, the coolant passing through the heat exchange module 240 without heat exchange can move to the component thermal management system 200 and can be used for cooling of components.

In the coolant blocking mode, because both the coolant flow path 246a of the heat exchange part 246 and the bypass flow path part 247 are closed, the coolant does not flow through the radiator 227 and the heat exchange module 240. Because the coolant does not flow therebetween, heat exchange is not performed between the coolant and the refrigerant in the heat exchange module 240.

The configuration of the vehicle thermal management device and the vehicle thermal management system according to an embodiment of the present disclosure has been described above. Hereinafter, the main operation mode of the thermal management system will be described below with reference to FIGS. 19 to 27 for an embodiment of the present disclosure.

In the description below, the controller 10 can control the operations of the operating elements such as the compressor 110, the first expansion valve 130, the second expansion valve 160, the third expansion valve 191, the water pumps 211 and 221, the first valve 222, the second valve 224, the third valve 230, the water heater 223, the cooling fan 11, the valve device 248 of the heat exchange module 240, the air-conditioning blower 12, and the like, or any combination thereof.

FIG. 19 is a diagram showing a state in which battery cooling and interior cooling can be simultaneously performed. Specifically, this state can correspond to a mode in which battery cooling and interior cooling can be performed simultaneously during rapid battery charging of an electric vehicle and under severe conditions in hot weather.

In the mode shown in FIG. 19, water-cooled condensation in which additional condensation of the refrigerant can be performed by the coolant of the heat exchange module 240 in the receiver dryer 150, and heat dissipation to the outside air (heat of the coolant and the refrigerant is discharged to the outside air) in the radiator 227 and the external condenser 140 can be performed.

As shown in FIG. 19, while the compressor 110 can be driven and refrigerant discharged from the compressor 110 can circulate along the refrigerant line 2 of the cooling/heating system 100, the refrigerant can flow and circulate along a flow path so as to sequentially pass through the internal condenser 120, the first expansion valve 130, the external condenser 140, the receiver dryer 150, the external condenser 140, the second expansion valve 160, the evaporator 170, and the accumulator 180. At the same time, a part of the refrigerant can be distributed from the refrigerant line 2 to the chiller refrigerant line 3, sequentially pass through the third expansion valve 191 and the chiller 192, and can be recovered by the accumulator 180.

In this example, the opening state of the first expansion valve 130 can be controlled such that the refrigerant does not flow into the branch line 5 branching from the refrigerant line 2. The first expansion valve 130 can be controlled to allow the refrigerant to pass therethrough without expansion, and the refrigerant passing through the first expansion valve 130 then can discharge heat through heat exchange with outside air suctioned by the cooling fan 11 in the external condenser 140.

At this operation, while the outside air suctioned by the cooling fan 11 sequentially passes through the periphery of the radiator 227 and the external condenser 140, the outside air can sequentially exchange heat with the PE coolant inside the radiator 227 and the refrigerant inside the external condenser 140.

The refrigerant that has passed through the external condenser 140 then can move to the receiver dryer 150. Here, the heat exchange module 240 can be controlled to enter the heat exchange mode. Accordingly, the PE coolant that has undergone heat dissipation in the radiator 227 can pass through the heat exchange part 246 through the valve device of the heat exchange module 240. Thereafter, the PE coolant can be discharged from the heat exchange module 240.

While the PE coolant passes through the heat exchange part 246 of the heat exchange module 240, heat exchange can be performed between the PE coolant and the refrigerant inside the receiver dryer 150 in the heat exchange part 246, and the refrigerant inside the receiver dryer 150 can be cooled while discharging heat to the PE coolant. Thereafter, the refrigerant can be discharged from the receiver dryer 150.

The discharged refrigerant can flow along the refrigerant line 2. Here, a part of the refrigerant flowing along the refrigerant line 2 can be expanded to a low-temperature and low-pressure state while passing through the second expansion valve 160. The refrigerant expanded to the low-temperature and low-pressure state can pass through the inside of the evaporator 170 and can be recovered by the accumulator 180.

In the evaporator 170, heat exchange can be performed between the low-temperature refrigerant passing through the inside of the evaporator and air-to-be-conditioned blown by the air-conditioning blower (reference numeral "12" in FIG. 2). At this operation, conditioned air cooled by the refrigerant can be discharged into the vehicle interior, thereby cooling the vehicle interior.

The rest of the refrigerant that has been discharged from the receiver dryer 150 and then has moved along the refrigerant line 2 can be distributed to the chiller refrigerant line 3 and then can be expanded to a low-temperature and low-pressure state by the third expansion valve 191. Thereafter, the refrigerant expanded to the low-temperature and low-pressure state can pass through the chiller 192 and then can be recovered by the accumulator 180.

In the component thermal management system 200, the water pumps 211 and 221, that is, the water pump 211 of the battery thermal management system 210 and the water pump 221 of the PE thermal management system 220, can be driven respectively so as to allow the coolant to circulate along the coolant line 6 (hereinafter referred to as a "battery coolant line") of the battery thermal management system 210, the coolant line 7 (hereinafter referred to as a "PE coolant line") of the PE thermal management system 220, and the heater coolant line 8.

The battery coolant circulating along the battery coolant line 6 can undergo heat exchange with the low-temperature refrigerant expanded by the third expansion valve 191 while passing through the chiller 192. Here, the battery coolant cooled by the refrigerant can pass through the battery coolant passage part 213 along the battery coolant line 6. In this manner, cooling of the battery 212 can be performed while the battery coolant passes through the battery coolant passage part 213.

In the PE thermal management system 220, the PE coolant can sequentially circulate through the water pump 221, the PE coolant line 7, the first valve 222, the heater coolant line 8, the water heater 223, the heater coolant line 8, the PE coolant line 7, the third valve 230, the radiator 227, the heat exchange part 246 of the heat exchange module 240, the PE coolant line 7, and the water pump 221.

In this example, the water heater 223 is not operated, and thus, the PE coolant can pass through the heater coolant line 8 without being heated by the water heater 223. In this example, the PE coolant does not flow through the PE coolant passage part 226, the PE coolant line 7 on the inlet side and the outlet side of the PE coolant passage part 226, the connection line 9, the chiller 192, and the PE coolant line 7 on the inlet side and the outlet side of the chiller.

The above-described coolant flow state may be implemented when the opening states of the first valve 222, the second valve 224, and the third valve 230 are controlled by the controller 10. Because the opening states of the first valve 222, the second valve 224, and the third valve 230 may be understood by a flow path through which the PE coolant moves and circulates, a detailed description thereof will be omitted.

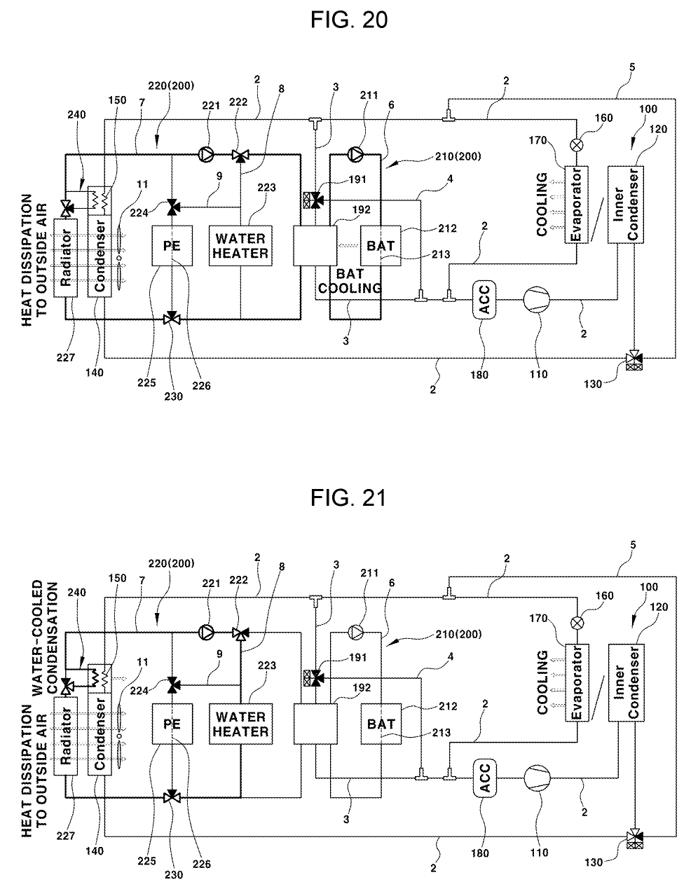

Next, FIG. 20 is a diagram showing a state in which battery cooling and interior cooling can be simultaneously performed. Unlike the mode shown in FIG. 19, the mode shown in FIG. 20 is a mode in which the heat of the coolant that has cooled the battery 212 can be discharged only through the radiator 227. In the mode shown in FIG. 20, only heat dissipation to the outside air (heat of the refrigerant is discharged to the outside air) is performed in the radiator 227 without water-cooled condensation by the coolant of the heat exchange module 240.

As shown in the drawing, while the compressor 110 can be driven and all of the refrigerant discharged from the compressor 110 can circulate along the refrigerant line 2 of the cooling/heating system 100, the refrigerant can flow and circulate along a flow path so as to sequentially pass through the internal condenser 120, the first expansion valve 130, the external condenser 140, the receiver dryer 150, the external condenser 140, the second expansion valve 160, the evaporator 170, and the accumulator 180.

At this operation, the opening state of the first expansion valve 130 can be controlled such that the refrigerant does not flow into the branch line 5 branching from the refrigerant line 2. The refrigerant can be not distributed to the chiller refrigerant line 3, and thus, the refrigerant does not pass through the third expansion valve 191 and the chiller 192 in this example.

The first expansion valve 130 can be controlled to allow the refrigerant to pass therethrough without expansion, and the refrigerant that has passed through the first expansion valve 130 can be condensed while dissipating heat through heat exchange with the outside air suctioned by the cooling fan 11 in the external condenser 140. Thereafter, the refrigerant that has passed through the external condenser 140 can move to the receiver dryer 150, and at this operation, the heat exchange module 240 can be controlled to enter the bypass mode.

Accordingly, the refrigerant can be discharged without performing heat exchange with the PE coolant in the receiver dryer 150, and the refrigerant discharged from the receiver dryer 150 can flow to the second expansion valve 160 along the refrigerant line 2.

Thereafter, while passing through the second expansion valve 160, the refrigerant can be expanded to a low-temperature and low-pressure state. Then, the refrigerant expanded to the low-temperature and low-pressure state can pass through the inside of the evaporator 170 and can be recovered by the accumulator 180.

In the evaporator 170, heat exchange can be performed between the low-temperature refrigerant passing through the inside of the evaporator and air-to-be-conditioned blown by the air-conditioning blower (reference numeral "12" in FIG. 2). At this operation, conditioned air cooled by the refrigerant can be discharged into the vehicle interior, thereby cooling the vehicle interior.

In the component thermal management system 200 of an embodiment, the water pumps 211 and 221, that is, the water pump 211 of the battery thermal management system 210 and the water pump 221 of the PE thermal management system 220, can be driven respectively so as to allow the coolant to circulate along the battery coolant line 6 and the PE coolant line 7.

In this example, in the PE thermal management system 220, the PE coolant can sequentially circulate through the water pump 221, the PE coolant line 7, the first valve 222, the PE coolant line 7, the chiller 192, the PE coolant line 7, the third valve 230, the radiator 227, the valve device of the heat exchange module 240, the bypass flow path part 247, the PE coolant line 7, and the water pump 221.

The PE coolant can exchange heat with the outside air suctioned by the cooling fan 11 while passing through the radiator 227, and heat can be discharged to the outside air from the PE coolant passing through the inside of the radiator 227.

In this example, the PE coolant of the PE thermal management system 220 does not flow to the heater coolant line 8 and the water heater 223, and the coolant does not flow through the PE coolant passage part 226, the PE coolant line 7 on the inlet side and the outlet side of the PE coolant passage part 226, the connection line 9, the chiller 192, and the PE coolant line 7 on the inlet side and the outlet side of the chiller 192.

The battery coolant circulating along the battery coolant line 6 can pass through the chiller 192 and the battery coolant passage part 213. Here in this example, because the refrigerant does not pass through the chiller 192, heat exchange between the refrigerant and the battery coolant is not performed in the chiller 192.

However, heat exchange can be performed between the battery coolant of the battery thermal management system 210 and the PE coolant of the PE thermal management system 220 in the chiller 192. As a result, the heat of the battery coolant that has cooled the battery 212 while passing through the battery coolant passage part 213 can be transferred to the PE coolant in the chiller 192 and then can be discharged to the outside air from the radiator 227.

Next, FIG. 21 is a diagram showing a state in the maximum cooling mode, in which maximum subcooling can be secured and maximum cooling can be performed. The mode shown in FIG. 21 is different from the mode shown in FIG. 19 in that the battery coolant does not circulate through the battery thermal management system 210, and the coolant is not distributed to the chiller coolant line 3. The remaining coolant circulation and PE coolant circulation have no difference in circulation paths between the two modes.

In the maximum cooling mode shown in FIG. 21 as well, water-cooled condensation in which additional condensation of the refrigerant by the coolant of the heat exchange module 240 can be performed in the receiver dryer 150, and heat dissipation to the outside air (heat of the coolant and the refrigerant can be discharged to the outside air) in the radiator 227 and the external condenser 140 can be performed.

In the maximum cooling mode shown in FIG. 21, only interior cooling is performed. That is, unlike the modes shown in FIGS. 19 and 20, cooling of the battery 212 is not performed, and heat exchange between the battery coolant and the refrigerant is not performed in the chiller 192. As a result, the heat of the battery 212 can be not transferred to the refrigerant through the coolant in this mode.

Heat exchange can be performed between the PE coolant passing through the heat exchange part 246 of the heat exchange module 240 after being discharged from the radiator 227 and the refrigerant passing through the inside of the receiver dryer 150. At this operation, heat of the refrigerant can be transferred to the PE coolant such that the refrigerant can be cooled. As a result, subcooling may be secured.

The refrigerant cooled in the receiver dryer 150 can flow along the refrigerant line 2 and can be supplied to the second expansion valve 160. Thereafter, the refrigerant can be expanded to a low-temperature and low-pressure state in the second expansion valve 160 and then flow to the evaporator 170.

Afterwards, while the low-temperature refrigerant passes through the inside of the evaporator 170, the refrigerant can exchange heat with air-to-be-conditioned passing through the periphery of the evaporator 170. Here, conditioned air cooled by the refrigerant can be discharged into the vehicle interior, thereby cooling the vehicle interior.

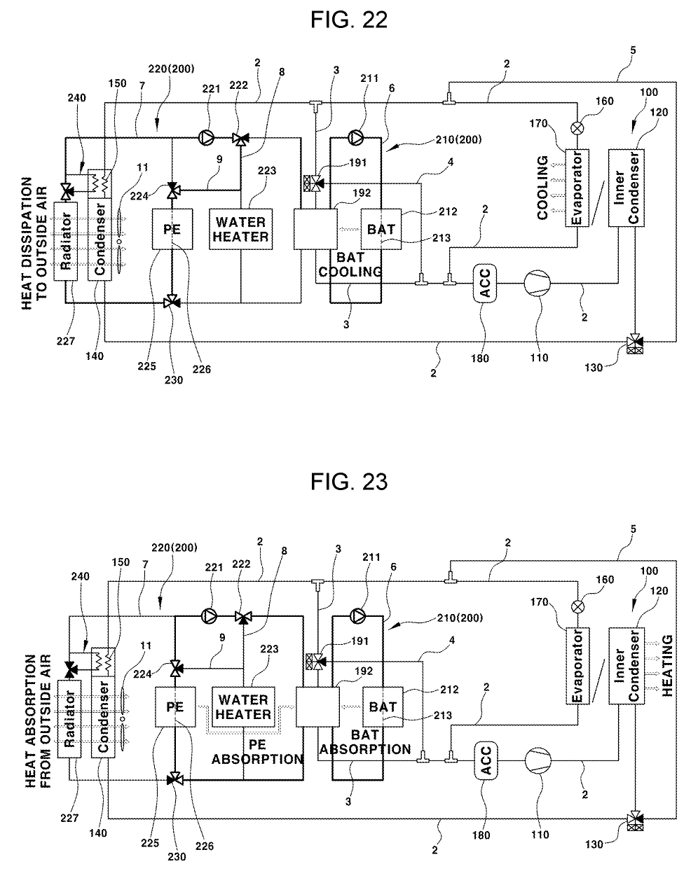

FIG. 22 is a diagram showing a state in the simultaneous cooling mode in which the battery cooling, the PE system cooling, and interior cooling can be performed simultaneously. In this mode, heat dissipation to the outside air (heat of the coolant and the refrigerant is discharged to the outside air) can be performed in the radiator 227 and the external condenser 140 without water-cooled condensation by the coolant of the heat exchange module 240. Refrigerant circulation of this mode can be the same as that of the mode shown in FIG. 19.

As shown in FIG. 22, while the compressor 110 is driven and refrigerant discharged from the compressor 110 circulates along the refrigerant line 2 of the cooling/heating system 100, the refrigerant can flow and circulate along a flow path so as to sequentially pass through the internal condenser 120, the first expansion valve 130, the external condenser 140, the receiver dryer 150, the external condenser 140, the second expansion valve 160, the evaporator 170, and the accumulator 180. Simultaneously, a part of the refrigerant from the refrigerant line 2 is distributed to the chiller refrigerant line 3, sequentially passes through the third expansion valve 191 and the chiller 192, and is recovered by the accumulator 180.

At this operation, the opening state of the first expansion valve 130 can be controlled so as to prevent the refrigerant from flowing into the branch line 5 branching from the refrigerant line 2. The first expansion valve 130 can be controlled so as to allow the refrigerant to pass therethrough without expansion. Then, the refrigerant passing through the first expansion valve 130 can be condensed while discharging heat through heat exchange with outside air suctioned by the cooling fan 11 in the external condenser 140.

Here, the outside air suctioned by the cooling fan 11 can sequentially pass through the periphery of the radiator 227 and the periphery of the external condenser 140. Then, the outside air can sequentially exchange heat with the PE coolant inside the radiator 227 and the refrigerant inside the external condenser 140.

The refrigerant that has passed through the external condenser 140 then can flow to the receiver dryer 150. Here, the heat exchange module 240 can be controlled to enter the bypass mode. Therefore, the refrigerant can be discharged without heat exchange with the PE coolant in the receiver dryer 150.

The refrigerant discharged in this manner can flow along the refrigerant line 2, and a part of the refrigerant flowing along the refrigerant line 2 can be expanded to a low-temperature and low-pressure state while passing through the second expansion valve 160. The refrigerant expanded to the low-temperature and low-pressure state can pass through the inside of the evaporator 170 and can be recovered by the accumulator 180.

In the evaporator 170, heat exchange can be performed between the low-temperature refrigerant passing through the inside of the evaporator and air-to-be-conditioned blown by the air-conditioning blower (reference numeral "12" in FIG. 2). At this operation, conditioned air cooled by the refrigerant can be discharged into the vehicle interior, thereby cooling the vehicle interior.

The rest of the refrigerant that has been discharged from the receiver dryer 150 and then has moved along the refrigerant line 2 can be distributed to the chiller refrigerant line 3 and then can be expanded to a low-temperature and low-pressure state by the third expansion valve 191. Thereafter, the refrigerant expanded to the low-temperature and low-pressure state can pass through the chiller 192 and then can be recovered by the accumulator 180.

In the component thermal management system 200 of an embodiment, the water pump 211 of the battery thermal management system 210 can be driven to allow the battery coolant to circulate along the battery coolant line 6. The water pump 221 of the PE thermal management system 220 can be driven to allow the PE coolant to circulate along the PE coolant line 7.

The battery coolant circulating along the battery coolant line 6 can undergo heat exchange with the low-temperature refrigerant expanded by the third expansion valve 191 while passing through the chiller 192. At this operation, the battery coolant cooled by the refrigerant can pass through the battery coolant passage part 213 along the battery coolant line 6. In this manner, the battery 212 can be cooled while the battery coolant passes through the battery coolant passage part 213.

In the PE thermal management system 220 of an embodiment, the PE coolant can sequentially circulate through the water pump 221, the PE coolant line 7, the first valve 222, the heater coolant line 8, the connection line 9, the second valve 224, the PE coolant line 7, the PE coolant passage part 226, the PE coolant line 7, the third valve 230, the PE coolant line 7, the radiator 227, the valve device of the heat exchange module 240, the bypass flow path part 247, the PE coolant line 7, and the water pump 221.

In this manner, the PE coolant can cool the PE system 225 while passing through the PE coolant passage part 226. The PE coolant can pass through only a part of the heater coolant line 8 and not pass through the water heater 223. In this example, the PE coolant does not flow through the chiller 192 and the PE coolant line 7 of the inlet 142 and the outlet 143 of the chiller.

The coolant flow state may be implemented when the opening states of the first valve 222, the second valve 224, and the third valve 230 are controlled by the controller 10. Because the opening states of the first valve 222, the second valve 224, and the third valve 230 may be understood by a flow path through which the PE coolant moves and circulates, a detailed description thereof will be omitted.

In the mode shown in FIG. 22, the PE coolant that has cooled the PE system 225 can discharge heat to the outside through heat exchange with the outside air while passing through the radiator 227, and the battery coolant that has cooled the battery 212 can be cooled while discharging heat to the refrigerant through heat exchange with the refrigerant in the chiller 192.

In this manner, the PE coolant cooled by the outside air in the radiator 227 can cool the component of the PE system 225 while passing through the PE coolant passage part 226, and the battery coolant cooled by the refrigerant in the chiller 192 can cool the battery 212 while passing through the battery coolant passage part 213.

FIG. 23 is a diagram showing a state in which the heat pump is in the heating mode. In this mode, to implement the heat pump, refrigerant passing through the inside of the external condenser 140 can be suctioned by the cooling fan 11 so as to absorb heat from the outside air passing through the periphery of the external condenser 140, thereby performing "heat absorption from the outside air" (heat of the outside air is transferred to and absorbed by the refrigerant).

As shown in FIG. 23, the compressor 110 can be driven, and all of the refrigerant discharged from the compressor 110 can flow along the refrigerant line 2 of the cooling/heating system 100, sequentially pass through the internal condenser 120, the first expansion valve 130, the external condenser 140, and the receiver dryer 150, and then flow to the chiller refrigerant line 3.

In this example, the opening state of the first expansion valve 130 can be controlled so as to prevent the refrigerant from flowing into the branch line 5 branching from the refrigerant line 2. In the heat exchange module 240 installed in the receiver dryer 150, in an embodiment, the coolant does not pass through the radiator 227 and the heat exchange module 240 and, as such, heat exchange between the coolant and the refrigerant is not performed.

Then, while all of the refrigerant flows along the chiller refrigerant line 3, the refrigerant can pass through the third expansion valve 191 and the chiller 192. Thereafter, the refrigerant can flow again to the refrigerant line 2 and can be recovered by the accumulator 180. Then, the refrigerant of the accumulator 180 can be suctioned again by the compressor 110. Thereafter, the refrigerant can be discharged through the refrigerant line 2 and circulate along the same path.

The refrigerant can be compressed in the compressor 110 and can be discharged in a high-temperature and high-pressure state. The refrigerant in the high-temperature and high-pressure state can be blown by the air-conditioning blower 12 while passing through the inside of the internal condenser 120 and exchange heat with air-to-be-conditioned passing through the periphery of the internal condenser 120.

While exchanging heat with the high-temperature refrigerant in this manner, the air-to-be-conditioned can be heated, and conditioned air heated by the high-temperature refrigerant in the internal condenser 120 can be discharged into the vehicle interior, thereby heating the vehicle interior.

The refrigerant passing through the internal condenser 120 can flow to the first expansion valve 130 along the refrigerant line 2 and can be expanded to a low-temperature and low-pressure state while passing through the first expansion valve 130. Then, the refrigerant passing through the first expansion valve 130 can flow along the refrigerant line 2 and can be supplied to the external condenser 140. Here, while passing through the external condenser 140, the refrigerant can receive heat from the outside air suctioned by the cooling fan 11.

Afterwards, the refrigerant that has completed heat absorption while passing through the external condenser 140 can pass through the receiver dryer 150 and then flow along the refrigerant line 2. Then, the refrigerant can flow to the chiller refrigerant line 3 and pass through the third expansion valve 191.

While passing through the third expansion valve 191, the refrigerant can be expanded to a low-temperature and low-pressure state and can be supplied to the chiller 192. The expanded low-temperature and low-pressure refrigerant can exchange heat with the battery coolant and the PE coolant while passing through the chiller 192.

In the chiller 192, the refrigerant can receive heat from the battery coolant and heat from the PE coolant, flow along the chiller refrigerant line 3 and the refrigerant line 2 in the chiller 192, and can be recovered by the accumulator 180.

In this manner, the refrigerant can absorb the heat of the battery 212 through the battery coolant, thereby performing battery heat absorption ("BAT heat absorption") between the battery 212 and the chiller 192, and the refrigerant can absorb the heat of the PE system 225 through the PE coolant, thereby performing PE heat absorption between the PE system 225 and the chiller 192.

In the component thermal management system 200 of an embodiment, the water pumps 211 and 221, that is, the water pump 211 of the battery thermal management system 210 and the water pump 221 of the PE thermal management system 220, can be driven respectively to allow the coolant to circulate along the battery coolant line 6 and the PE coolant line 7.

The battery coolant circulating along the battery coolant line 6 can exchange heat with the low-temperature refrigerant expanded by the third expansion valve 191 while passing through the chiller 192. At this operation, the battery coolant cooled by the refrigerant can flow along the battery coolant line 6 and pass through the battery coolant passage part 213.

Thereby, heat can be transferred from the battery coolant to the refrigerant in the chiller 192. Here, the heat of the battery 212 can be transferred to the refrigerant through the battery coolant. Thereafter, the heat can be transferred to air-to-be-conditioned, and conditioned air can be supplied to the vehicle interior, thereby heating the vehicle interior. Because the battery coolant cooled by the refrigerant can pass through the battery coolant passage part 213, cooling of the battery 212 may be performed.

In the PE thermal management system 220 of an embodiment, the PE coolant can sequentially circulate through the water pump 221, the PE coolant line 7, the first valve 222, the PE coolant line 7, the chiller 192, the PE coolant line 7, the third valve 230, the PE coolant line 7, the PE coolant passage part 226, the PE coolant line 7, the third valve 230, and the water pump 221.

In this example, the coolant does not flow from the first valve 222 to the heater coolant line 8, and the coolant also does not flow from the third valve 230 to the connection line 9. In this example, the coolant does not flow from the second valve 224 to the radiator 227 and the PE coolant line 7 and the heat exchange module 240 connected thereto.

The PE coolant circulating along the PE coolant line 7 can exchange heat with the low-temperature refrigerant while passing through the chiller 192. At this operation, the PE coolant cooled by the refrigerant can flow along the PE coolant line 7 and pass through the PE coolant passage part 226.

Accordingly, heat can be transferred from the PE coolant to the refrigerant in the chiller 192. Here, the heat of the PE system 225 can be transferred to the refrigerant through the PE coolant. Thereafter, the heat can be transferred to air-to-be-conditioned, and conditioned air can be supplied to the vehicle interior, thereby heating the vehicle interior. Because the PE coolant cooled by the refrigerant can pass through the PE coolant passage part 226, cooling of the PE system 225 may be achieved.

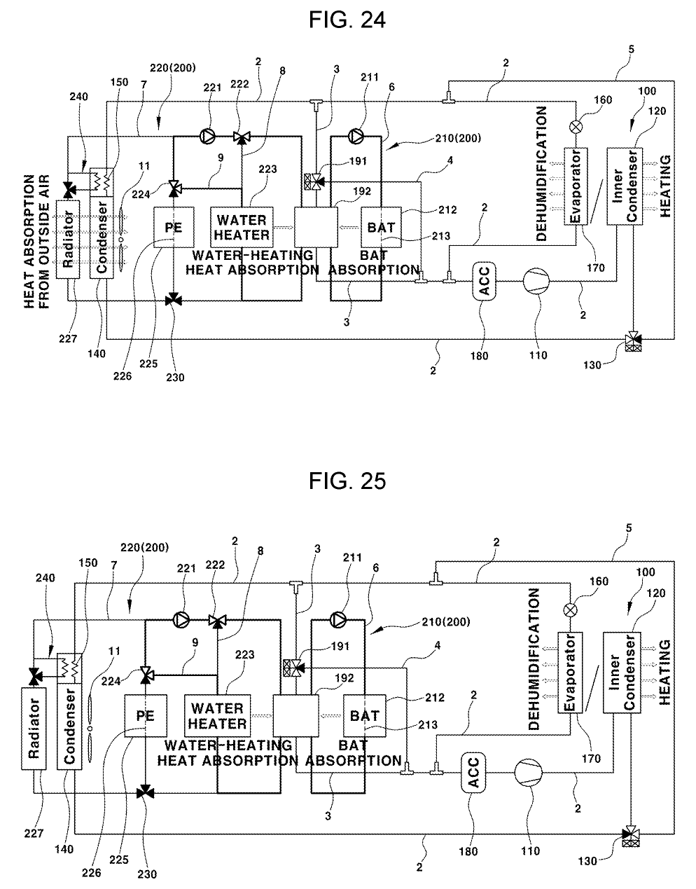

FIG. 24 is a diagram showing a mode in which heating and dehumidification by a first heat pump are simultaneously performed. In this mode, to implement the heat pump, the refrigerant passing through the inside of the external condenser 140 can absorb heat from the outside air passing through the periphery of the external condenser 140, thereby performing "heat absorption from the outside air" (heat of the outside air is transferred to and absorbed by the refrigerant).

Heat pump boosting ("water-heating heat absorption") in which heat is transferred to the refrigerant using the water heater 223, and battery heat absorption ("BAT heat absorption") in which the refrigerant absorbs heat from the battery 212 through the battery coolant can be performed.

As shown in FIG. 24, the compressor 110 can be driven, and the refrigerant discharged from the compressor 110 can flow along the refrigerant line 2 of the cooling/heating system 100, can sequentially pass through the internal condenser 120, the first expansion valve 130, the external condenser 140, the receiver dryer 150, and the external condenser 140, and is distributed from the outlet side of the external condenser 140 to the refrigerant line 2 on which the second expansion valve 160 is installed and the chiller refrigerant line 3 on which the third expansion valve 191 and the chiller 192 are installed.

At this operation, the opening state of the first expansion valve 130 can be controlled so as to prevent the refrigerant from flowing to the branch line 5 branching from the refrigerant line 2. In the heat exchange module 240 installed in the receiver dryer 150, in an embodiment, the coolant does not pass through the radiator 227 and the heat exchange module 240 and, as such, heat exchange between the coolant and the refrigerant is not performed.

The refrigerant can be compressed by the compressor 110 and can be discharged in a high-temperature and high-pressure state. Here, the refrigerant in the high-temperature and high-pressure state can be blown by the air-conditioning blower 12 while passing through the inside of the internal condenser 120 and can exchange heat with air-to-be-conditioned passing through the periphery of the internal condenser 120.

In this manner, the air-to-be-conditioned can be heated while exchanging heat with the high-temperature refrigerant, and conditioned air heated by the high-temperature refrigerant in the internal condenser 120 can be discharged into the vehicle interior, thereby heating the vehicle interior.

The refrigerant passing through the internal condenser 120 can flow to the first expansion valve 130 along the refrigerant line 2 and can be expanded to a low-temperature and low-pressure state while passing through the first expansion valve 130. Then, the refrigerant passing through the first expansion valve 130 can flow along the refrigerant line 2 and can be supplied to the external condenser 140. While passing through the external condenser 140, the refrigerant can receive heat from the outside air suctioned by the cooling fan 11.

Afterwards, the refrigerant that has completed heat absorption while passing through the external condenser 140 can pass through the receiver dryer 150 and flow along the refrigerant line 2. Here, a part of the refrigerant can flow to the refrigerant line 2 on which the first expansion valve 130 can be installed and then can be supplied to the second expansion valve 160.

Then, while passing through the second expansion valve 160, the refrigerant can be expanded to a low-temperature and low-pressure state, and the low-temperature and low-pressure refrigerant that has passed through the second expansion valve 160 can be supplied to the evaporator 170 through the refrigerant line 2.

Thereafter, the low-temperature refrigerant passing through the inside of the evaporator 170 can exchange heat with air-to-be-conditioned that is blown by the air-conditioning blower 12 and pass through the periphery of the evaporator 170. At this operation, conditioned air that has completed heat exchange with the low-temperature refrigerant can be discharged into the vehicle interior. In this manner, the conditioned air can be used for dehumidification of the vehicle interior.

The refrigerant that has passed through the evaporator 170 can flow through the refrigerant line 2 and can be recovered by the accumulator 180. Then, the refrigerant can be suctioned by the compressor 110 from the accumulator 180 and can be discharged through the refrigerant line 2 to circulate along the same path.

A part of the refrigerant discharged from the receiver dryer 150 can flow from the refrigerant line 2 to the chiller refrigerant line 3 and pass through the third expansion valve 191. While passing through the third expansion valve 191, the refrigerant can be expanded to a low-temperature and low-pressure state and can be supplied to the chiller 192. The expanded low-temperature and low-pressure refrigerant can exchange heat with the battery coolant and the PE coolant while passing through the chiller 192.

Therefore, in the chiller 192, the refrigerant can receive heat from the battery coolant and heat from the PE coolant, flow along the chiller refrigerant line 3 and the refrigerant line 2 in the chiller 192, and can be recovered by the accumulator 180. Afterwards, the refrigerant can be suctioned again by the compressor 110 from the accumulator 180 and can be discharged through the refrigerant line 2 and circulate along the same path.

The battery coolant that exchanges heat with the refrigerant in the chiller 192 can be coolant that has received heat from the battery 212 while passing through the battery coolant passage part 213, and the PE coolant that exchanges heat with the refrigerant in the chiller 192 can be heated by the water heater 223. The PE coolant can be heated by the water heater 223 while circulating along the PE coolant line 7, and then can transfer heat to the refrigerant in the chiller 192.

In this manner, water-heating heat absorption can be performed between the water heater 223 and the chiller 192. Here, in the water-heating heat absorption, the refrigerant can absorb, from the coolant, heat of the water heater 223. Battery heat absorption ("BAT heat absorption") can be performed between the battery 212 and the chiller 192. In the battery heat absorption, the refrigerant can absorb heat from the battery 212 through the battery coolant.

In the component thermal management system 200 of an embodiment, the water pumps 211 and 221, that is, the water pump 211 of the battery thermal management system 210 and the water pump 221 of the PE thermal management system 220, can be driven respectively so as to allow the coolant to circulate along the battery coolant line 6 and the PE coolant line 7.

The battery coolant circulating along the battery coolant line 6 can undergo heat exchange with the low-temperature refrigerant expanded by the third expansion valve 191 while passing through the chiller 192. At this operation, the battery coolant cooled by the refrigerant can flow along the battery coolant line 6 and pass through the battery coolant passage part 213.

In this manner, heat can be transferred from the battery coolant to the refrigerant in the chiller 192. Here, the heat of the battery 212 can be transferred to the refrigerant through the battery coolant. Then, the heat can be transferred to air-to-be-conditioned, and conditioned air can be supplied to the vehicle interior, thereby heating the vehicle interior. Because the battery coolant cooled by the refrigerant passes through the battery coolant passage part 213, cooling of the battery 212 may be performed in an embodiment.

In the PE thermal management system 220 of an embodiment, the PE coolant can sequentially circulate through the water pump 221, the PE coolant line 7, the first valve 222, the PE coolant line 7, the chiller 192, the PE coolant line 7, the heater coolant line 8, the water heater 223, the heater coolant line 8, the connection line 9, the third valve 230, the PE coolant line 7, and the water pump 221.

In this example, the first valve 222 can block the flow path of the heater coolant line 8 such that the coolant does not flow to the heater coolant line 8. In the third valve 230, the flow path of the connection line 9 can be opened, but the flow path of the PE coolant line 7 connected to the PE coolant passage part 226 of the PE system 225 can be blocked.

In the second valve 224, all of the connected flow paths can be blocked. Here, the flow path of the PE coolant line 7 connected to the PE coolant passage part 226 of the PE system 225 can be blocked, and the flow path of the PE coolant line 7 connected to the second radiator 227 can be also blocked. As a result, in this example, the coolant does not flow to the radiator 227 and the heat exchange module 240.

The PE coolant circulating along the PE coolant line 7 can be heated while passing through the water heater 223, and transfer heat to the low-temperature refrigerant while passing through the chiller 192. Therefore, heat can be transferred from the PE coolant to the refrigerant in the chiller 192. Here, the heat of the water heater 223 can be transferred to the refrigerant through the PE coolant. Then, the heat can be transferred to the air-to-be-conditioned, and then conditioned air can be supplied to the vehicle interior, thereby heating the vehicle interior.

FIG. 25 is a diagram showing a mode in which heating and dehumidification by a second heat pump can be simultaneously performed. In this example, the circulation path of coolant can be the same as that of the mode shown in FIG. 24. However, the refrigerant in this mode can have a different circulation path from that of the mode shown in FIG. 24.

In the mode shown in FIG. 25, the refrigerant is not supplied to the external condenser 140, and therefore, "heat absorption from the outside air" in the mode shown in FIG. 24, that is, "heat absorption from the outside air" in which the refrigerant absorbs heat of the outside air in the external condenser 140 is not performed.

However, the heat pump boosting ("water-heating heat absorption") in which heat is transferred to the refrigerant using the water heater 223, and the battery heat absorption ("BAT heat absorption") in which the refrigerant absorbs heat of the battery 212 through the battery coolant can be performed in the same manner as in FIG. 24.

As shown in FIG. 25, the compressor 110 can be driven, and the refrigerant discharged from the compressor 110 can flow along the refrigerant line 2 of the cooling/heating system 100, pass through the internal condenser 120, and flow to the branch line 5 from the first expansion valve 130.

While the high-temperature and high-pressure refrigerant compressed by the compressor 110 passes through the internal condenser 120, heat exchange can be performed between the refrigerant passing through the inside of the internal condenser 120 and air-to-be-conditioned that is blown by the air-conditioning blower 12 and pass through the periphery of the internal condenser 120.

At this operation, the air-to-be-conditioned can receive heat from the refrigerant in the internal condenser 120, and conditioned air heated by the refrigerant in the internal condenser 120 can be discharged into the vehicle interior, thereby heating the vehicle interior.

The refrigerant passing through the internal condenser 120 can flow along the refrigerant line 2 and pass through the first expansion valve 130. Here in this example, all of the refrigerant passing through the first expansion valve 130 can be discharged only through the branch line 5, not through the refrigerant line 2 connected to the external condenser 140.

To this end, the first expansion valve 130 can be controlled by the controller 10 to allow the refrigerant line 2 on the outlet side of the internal condenser 120 and the branch line 5 to communicate with each other, and to block the flow path of the refrigerant line 2 connected to the external condenser 140. At this operation, the refrigerant is not expanded in the first expansion valve 130 and can be discharged as is through the branch line 5.

Afterwards, a part of the refrigerant that has moved along the branch line 5 can be distributed and flow to the refrigerant line 2 on which the second expansion valve 160 can be installed, and the rest of the refrigerant can be distributed and flow to the refrigerant line 2 to which the chiller refrigerant line 3 can be connected.

In this manner, a part of the refrigerant that has passed through the branch line 5 can flow along the refrigerant line 2 and can be supplied to the second expansion valve 160. Here in this example, while passing through the second expansion valve 160, the refrigerant can be expanded to a low-temperature and low-pressure state.

Then, the low-temperature refrigerant that has passed through the second expansion valve 160 can be blown by the air-conditioning blower 12 while passing through the inside of the evaporator 170 and exchange heat with air-to-be-conditioned passing through the periphery of the evaporator 170.

In this example, heat of the air-to-be-conditioned can be discharged to the refrigerant, and the air-to-be-conditioned can be cooled by the refrigerant. Therefore, conditioned air that has discharged heat to the low-temperature refrigerant in the evaporator 170 can be discharged into the vehicle interior, thereby performing dehumidification of the vehicle interior.

As described above, the refrigerant that has passed through the evaporator 170 can flow along the refrigerant line 2 and can be recovered by the accumulator 180. Then, gaseous refrigerant from the accumulator 180 can be suctioned again by the compressor 110 and can be discharged through the refrigerant line 2. Then, the gaseous refrigerant can circulate again through the refrigerant circulation path as described above.

Because the flow path of the refrigerant line 2 connected from the first expansion valve 130 to the external condenser 140 can be blocked in this example, the refrigerant does not flow through the receiver dryer 150, the external condenser 140, and the refrigerant line 2 connected thereto. As a result, the rest of the refrigerant that has passed through the branch line 5 can flow from the refrigerant line 2 to the chiller refrigerant line 3.

Thereafter, the refrigerant that has moved along the chiller refrigerant line 3 to the third expansion valve 191 can be expanded to a low-temperature and low-pressure state while passing through the third expansion valve 191. Then, the low-temperature and low-pressure refrigerant expanded in the third expansion valve 191 can pass through the chiller 192, flow along the chiller refrigerant line 3 and the refrigerant line 2, and can be recovered by the accumulator 180.

While passing through the chiller 192, the refrigerant can receive heat from the battery coolant and heat from the PE coolant. Then, the refrigerant can flow along the chiller refrigerant line 3 and the refrigerant line 2 in the chiller 192 and can be recovered by the accumulator 180. Thereafter, gaseous refrigerant from the accumulator 180 can be suctioned again by the compressor 110 and can be discharged through the refrigerant line 2. In this manner, the gaseous refrigerant can circulate again through the refrigerant circulation path as described above.

In this example, the battery coolant that exchanges heat with the refrigerant in the chiller 192 can be coolant that has received heat from the battery 212 while passing through the battery coolant passage part 213, and the PE coolant that exchanges heat with the refrigerant in the chiller 192 has been heated by the water heater 223. The PE coolant can be heated by the water heater 223 while circulating along the PE coolant line 7, and then can transfer heat to the refrigerant in the chiller.

In this manner, water-heating heat absorption can be performed between the water heater 223 and the chiller 192. Here in this example, in the water-heating heat absorption, the refrigerant can absorb the heat of the water heater 223 from the coolant, and battery heat absorption ("BAT heat absorption") can be performed between the battery 212 and the chiller 192. Here in this example, in the battery heat absorption, the refrigerant can absorb the heat of the battery 212 through the battery coolant.

Because the circulation path of the coolant in the component thermal management system 200 can be the same as that of the mode shown in FIG. 24, and the water-heating heat absorption and the battery heat absorption can be performed in the same manner as in the mode shown in FIG. 24, a description of the coolant circulation will be omitted.

In this manner, in the mode shown in FIG. 25, heat can be transferred from the battery coolant to the refrigerant in the chiller 192. As a result, the heat of the battery 212 can be transferred to the refrigerant through the battery coolant. Then, the heat can be transferred to air-to-be-conditioned, and conditioned air can be supplied to the vehicle interior, thereby heating the vehicle interior. Because the battery coolant cooled by the refrigerant can pass through the battery coolant passage part 213, cooling of the battery 212 may be performed.

In the mode shown in FIG. 25, the PE coolant circulating along the PE coolant line 7 can be heated while passing through the water heater 223, and transfer heat to the low-temperature refrigerant while passing through the chiller 192. In this manner, heat can be transferred from the PE coolant to the refrigerant in the chiller 192. Here in this example, the heat of the water heater 223 can be transferred to the refrigerant through the PE coolant. Then, the heat can be transferred to air-to-be-conditioned, and conditioned air can be supplied to the vehicle interior, thereby heating the vehicle interior.

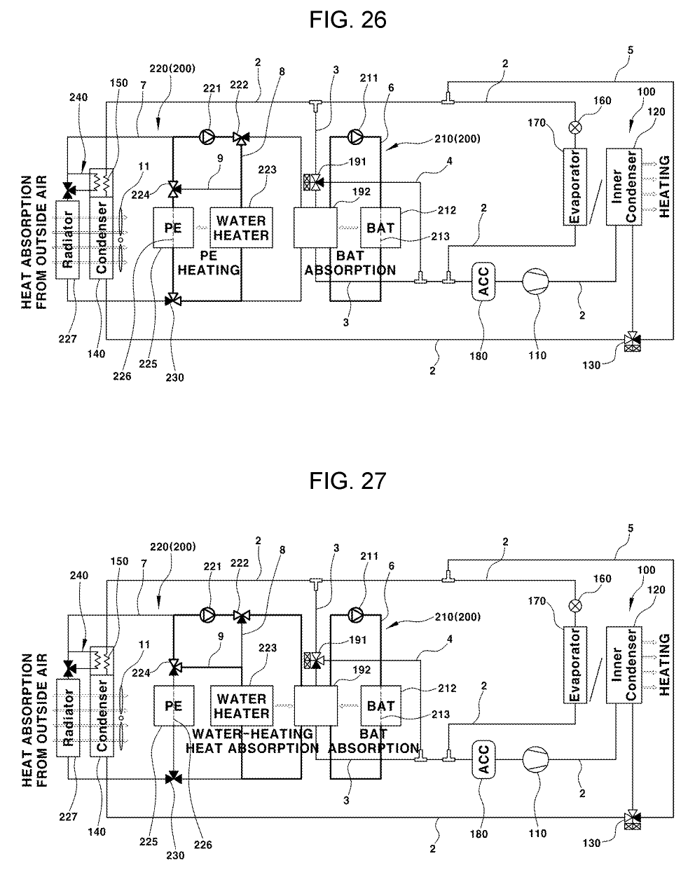

FIG. 26 is a diagram showing a heat pump heating mode in which heating of the vehicle interior can be performed. In this mode, PE heating can be is performed by operating the water heater to increase the temperature of the PE system. Through this configuration, the temperature of the PE system can be increased, and an effect of reducing the oil viscosity of the PE system may be obtained. FIG. 27 is a diagram showing another heat pump heating mode in which heating of the vehicle interior can be performed.

In the modes shown in FIGS. 26 and 27, because the circulation paths of the refrigerant and the coolant are shown by arrows, a description as to a process of circulation of the refrigerant and the coolant and an operation thereof will be omitted.

As can be apparent from the above description, according to a vehicle thermal management device and a vehicle thermal management system of an embodiment of the present disclosure, a new type of water-cooled condensing technology utilizing a receiver dryer and a radiator is provided, thereby making it possible not only to secure an additional subcooled area and increase an amount of heat dissipation, but also to effectively solve a heat load problem in an electric vehicle. In this manner, marketability of an electric vehicle may be improved.

According to an embodiment of the present disclosure, because heat from refrigerant is additionally discharged to the outside through a heat exchange module installed in the receiver dryer when rapid charging of a battery and cooling of the vehicle interior are performed simultaneously, a high-temperature and high-pressure state in a refrigerant system may be effectively stabilized, thereby having an effect of improving battery cooling and interior cooling performance.

Particularly, in an embodiment, system efficiency for thermal management may be increased by increasing utilization of a water heater. Even if the battery is rapidly charged in summer, air-conditioning performance can be reliably secured so as to provide pleasant air quality to an occupant in the vehicle using an embodiment. The range of a vehicle may be increased by improvement in system efficiency through additional heat dissipation using an embodiment. It can be possible to remove a conventional electric heater (for example, PTC heater) using an embodiment.

According to an embodiment of the present disclosure, the heat exchange module having a simple configuration can be installed in the receiver dryer, thereby making it possible not only to additionally secure a subcooled area without installation of a conventional water-cooled heat exchanger configured to perform heat exchange between refrigerant and coolant, but also to reduce the number of parts and simplify a system configuration as compared with a system using the conventional water-cooled heat exchanger.

As described above, the example embodiments of the present disclosure have been described in detail. Because the example embodiments described in this specification and the configurations shown in the drawings are only example embodiments of the present disclosure, the scopes of the present disclosure are not limited to the above-described embodiments. Various modifications and improvements made by those skilled in the art using the concepts of the present disclosure defined in the following claims also can fall within the scopes of the present disclosure.

What is claimed is:

1. A vehicle thermal management device comprising:
a radiator configured to perform heat exchange between a coolant and air;
a condenser configured to perform heat exchange between a refrigerant and the air;
a receiver dryer configured to remove moisture from the refrigerant discharged from the condenser, the receiver dryer being configured to separate liquid refrigerant of the refrigerant from gaseous refrigerant of the refrigerant; and
a heat exchange module connected to the radiator so as to allow the coolant to move therebetween, the heat exchange module being configured to selectively perform heat exchange between the refrigerant in the receiver dryer and the coolant supplied from the radiator.

2. The vehicle thermal management device of claim 1, wherein the heat exchange module is installed outside the receiver dryer.

3. The vehicle thermal management device of claim 2, wherein the heat exchange module has a coolant flow path configured to contact an outer surface of the receiver dryer.

4. The vehicle thermal management device of claim 2, wherein the heat exchange module has a coolant flow path disposed in a spiral shape around the receiver dryer.

5. The vehicle thermal management device of claim 1, wherein the heat exchange module comprises:
a heat exchange part comprising a coolant flow path, the heat exchange part being configured to perform heat exchange between the refrigerant in the receiver dryer and the coolant passing through the coolant flow path;
a bypass flow path part configured such that the coolant passes through the bypass flow path part while bypassing the heat exchange part; and
a valve device configured to control a flow of the coolant so as to allow the coolant discharged from the radiator to selectively flow through the heat exchange part or the bypass flow path part.

6. The vehicle thermal management device of claim 5, the heat exchange module further comprises a main body block having a coolant inlet and a coolant outlet, wherein the coolant flow path of the heat exchange part and the bypass flow path part directly connecting the coolant inlet to the coolant outlet are formed in the main body block.

7. The vehicle thermal management device of claim 5, wherein the valve device comprises:
a valve body configured to control, depending on a rotated position thereof, the flow of the coolant with respect to the bypass flow path part and the heat exchange part;
an actuator configured to rotate the valve body; and
a valve controller configured to control an operation of the actuator.

8. The vehicle thermal management device of claim 7, wherein the valve body comprises:
a first flow path part configured to allow, at a first rotation position of the valve body, a coolant inlet of the heat exchange module and the coolant flow path of the heat exchange part to communicate with each other;
a second flow path part configured to allow, at a second rotation position of the valve body, the coolant inlet and the bypass flow path part to communicate with each other; and
a blocking wall configured to cause, at a third rotation position of the valve body, the coolant inlet to be simultaneously blocked from the coolant flow path and the bypass flow path part.

9. The vehicle thermal management device of claim 1, wherein the heat exchange module comprises a main body block having a coolant inlet and a coolant outlet, wherein the main body block comprises:
an accommodation part configured to allow at least part of the receiver dryer to be inserted thereinto; and
a flow path groove formed in an inner surface of the accommodation part so as to form a coolant flow path between the coolant inlet and the coolant outlet, wherein the at least part of the receiver dryer is inserted into the accommodation part such that the flow path groove is sealed by an outer surface of the receiver dryer.

10. The vehicle thermal management device of claim 9, wherein the flow path groove is in the inner surface of the accommodation part so as to spirally surround a periphery of the at least part of the receiver dryer inserted into the accommodation part.

11. The vehicle thermal management device of claim 9, wherein the receiver dryer has a lower portion inserted into the accommodation part, wherein the lower portion of the receiver dryer is configured to be filled with the liquid refrigerant.

12. The vehicle thermal management device of claim 1, wherein the heat exchange module has a coolant outlet configured to allow the coolant that has completed the heat exchange with the refrigerant to be discharged therethrough, the coolant outlet being connected to a coolant line configured to provide thermal management of a battery and a power electronics (PE) system.

13. A vehicle thermal management system comprising:
a cooling-heating system configured to perform, using a refrigerant, cooling and heating of a vehicle interior;
a component thermal management system configured to perform, using the refrigerant and a first coolant, thermal management for a battery and a power electronics (PE) system; and
a heat exchange module connected to a radiator of the component thermal management system so as to allow the first coolant to move therebetween, the heat exchange module being configured to selectively perform heat exchange between the refrigerant in a receiver dryer and the first coolant supplied from the radiator, the receiver dryer being installed in a condenser of the cooling-heating system.

14. The vehicle thermal management system of claim 13, wherein the component thermal management system comprises:
a PE thermal management system comprising:
a first water pump,
a water heater configured to heat PE coolant,
a PE coolant passage part provided in a component of the PE system, wherein the radiator is configured to perform heat exchange between the PE coolant and air, and
a PE coolant line configured to connect the first water pump, the water heater, the PE coolant passage part, and the radiator to each other so as to allow the PE coolant to circulate therethrough;
a chiller connected to a chiller refrigerant line, wherein the chiller refrigerant line is connected to a refrigerant line of the cooling-heating system and the PE coolant line, wherein the chiller is configured to perform, while the refrigerant of the chiller refrigerant line and the PE coolant pass through the chiller, heat exchange between the refrigerant and the PE coolant; and
a chiller expansion valve installed on the chiller refrigerant line on an inlet side of the chiller.

15. The vehicle thermal management system of claim 14, wherein the component thermal management system further comprises a battery thermal management system, wherein the battery thermal management system comprises:
a second water pump,
a battery coolant passage part provided in the battery, and
a battery coolant line configured to connect the second water pump to the battery coolant passage part so as to allow battery coolant to circulate therethrough.

16. The vehicle thermal management system of claim 15, wherein the battery coolant line is connected to the chiller, and
wherein the chiller is configured to perform, while the refrigerant of the chiller refrigerant line, the PE coolant, and the battery coolant pass through the chiller, heat exchange between the refrigerant, the PE coolant, and the battery coolant.

17. The vehicle thermal management system of claim 14, wherein the PE thermal management system further comprises:
a heater coolant line branching from the PE coolant line between the first water pump and the chiller, the heater coolant line having the water heater connected thereto and installed thereon; and
a first valve installed on a branch point of the PE coolant line between the first water pump and the chiller, wherein the heater coolant line branches from the branch point.

18. The vehicle thermal management system of claim 17, wherein the PE thermal management system further comprises:
a connection line branching from the PE coolant line between the PE coolant passage part and the first water pump, the connection line being connected to the heater coolant line; and
a second valve installed on the branch point of the PE coolant line between the PE coolant passage part and the first water pump, wherein the connection line branches from the branch point.

19. The vehicle thermal management system of claim 13, wherein the heat exchange module is installed outside the receiver dryer.

20. The vehicle thermal management system of claim 13, wherein the heat exchange module comprises:
a heat exchange part comprising a coolant flow path, the heat exchange part being configured to perform heat exchange between the refrigerant in the receiver dryer and the first coolant passing through the coolant flow path;
a bypass flow path part configured such that the first coolant passes through the bypass flow path part while bypassing the heat exchange part; and
a valve device configured to control a flow of the first coolant so as to allow the first coolant discharged from the radiator to selectively flow through the heat exchange part or the bypass flow path part.
